(19) United States
(12) Patent Application Publication
(10) Pub. No.: US 2026/0371752 A1
(43) Pub. Date: Nov. 19, 2026

(54) PIXEL SENSOR ARRAYS AND METHODS OF FORMATION

(71) Applicant: Taiwan Semiconductor Manufacturing Company, Ltd., Hsinchu (TW)

(72) Inventors: Chun-Liang LU, Tainan City (TW); Chun-Hao LIN, Tainan City (TW); Chun-Hao CHOU, Tainan City (TW); Kuo-Cheng LEE, Tainan City (TW)

(21) Appl. No.: 19/749,705

(22) Filed: Jul. 22, 2026

Related U.S. Application Data
(63) Continuation of application No. 18/585,042, filed on Feb. 22, 2024.

(51) Int. Cl. H10F 39/00

(52) U.S. Cl. CPC H10F 39/8023; H10F 39/028; H10F 39/806

(57) ABSTRACT

An image sensor device may include one or more types of antireflection structures on a metal grid surrounding the pixel sensors in a pixel sensor array of the image sensor device. The antireflection structures may include an antireflective layer, nanostructures extending from the antireflective layer, and/or a plurality of cavities formed in the metal grid structure. The antireflection structures may be included in and/or on one or more surfaces of the metal grid structure to reduce the reflection of incident light, which may reduce the likelihood and/or magnitude of optical crosstalk between adjacent pixel sensors in the pixel sensor array.

### RELATED APPLICATION

This application is a continuation of U.S. patent application Ser. No. 18/585,042, filed Feb. 22, 2024, which is incorporated herein by reference in its entirety.

### BACKGROUND

A complementary metal oxide semiconductor (CMOS) image sensor may include a plurality of pixel sensors. A pixel sensor of the CMOS image sensor may include a transfer gate transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A-2C are diagrams of examples of an image sensor device described herein.

FIGS. 3A-3D are diagrams of examples of pixel sensor arrays of a sensor die described herein.

FIGS. 4A-4D are diagrams of examples of pixel sensor arrays of a sensor die described herein.

FIGS. 5A-5J are diagrams of examples of pixel sensor arrays of a sensor die described herein.

FIGS. 6A-6E are diagrams of an example implementation of forming a circuitry die (or a portion thereof) described herein.

FIGS. 7A-7F are diagrams of an example implementation of forming a sensor die (or a portion thereof) described herein.

FIGS. 8A-8F are diagrams of an example implementation of forming an image sensor device (or a portion thereof) described herein.

FIGS. 9A-9F are diagrams of an example implementation of forming nanostructures on a metal grid structure of a pixel sensor array described herein.

FIGS. 10A-10D are diagrams of an example implementation of forming nanostructures on a metal grid structure of a pixel sensor array described herein.

FIGS. 11A-11E are diagrams of an example implementation of forming antireflective layers on a metal grid structure of a pixel sensor array described herein.

FIGS. 12A-12C are diagrams of an example implementation of forming antireflective layers on a metal grid structure of a pixel sensor array described herein.

FIGS. 13A-13D are diagrams of an example implementation of forming cavities in a metal grid structure of a pixel sensor array described herein.

FIGS. 14A and 14B are diagrams of an example implementation of forming cavities in a metal grid structure of a pixel sensor array described herein.

FIG. 15 is a flowchart of an example process associated with forming a metal grid structure of a pixel sensor array.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An image sensor device (e.g., a complementary metal oxide semiconductor (CMOS) image sensor device or another type of image sensor device) is a type of electronic semiconductor device that uses pixel sensors to generate a photocurrent based on light received at the pixel sensors. The magnitude of the photocurrent may be based on the intensity of the light, based on the wavelength of the light, and/or based on another attribute of the light. The photocurrent is then processed to generate an electronic image, an electronic video, and/or another type of electronic signal.

Optical crosstalk can occur between adjacent pixel sensors in a pixel sensor array of an image sensor device. Optical crosstalk is a phenomenon whereby incident light passes through a pixel sensor at a non-orthogonal angle and is at least partially absorbed by a photodiode of an adjacent pixel sensor. Optical crosstalk can degrade the spatial resolution of the image sensor device, can reduce overall sensitivity of the image sensor device, can cause color mixing between pixel sensors of the image sensor device, and/or can lead to image noise after color correction.

In some cases, one or more structures are included in a pixel sensor array to reduce and/or minimize optical crosstalk between pixel sensors of the pixel sensor array. For example, a deep trench isolation (DTI) structure may be formed in a substrate such that the DTI structure surrounds the photodiodes of the pixel sensors in the pixel sensor array. As another example, a metal grid structure may be formed above the substrate, and may surround the pixel sensors in a similar manner as the DTI structure. The metal grid structure may be formed of one or more metal materials to facilitate reflection of incident light toward the photodiodes of the pixel sensors, thereby improving the quantum efficiency (QE) of the pixel array. However, some incident light may be reflected away from a pixel sensor and toward another pixel sensor, resulting in the incident light passing through multiple different types of color filters. This may result in optical crosstalk and associated color mixing between pixel sensors.

As described herein, an image sensor device may include one or more types of antireflection structures on a metal grid surrounding the pixel sensors in a pixel sensor array of the image sensor device. The antireflection structures may include an antireflective layer, nanostructures extending from the antireflective layer, and/or a plurality of cavities formed in the metal grid structure. The antireflection structures may be included in and/or on one or more surfaces of the metal grid structure to reduce the reflection of incident light, which may reduce the likelihood and/or magnitude of optical crosstalk between adjacent pixel sensors in the pixel sensor array.

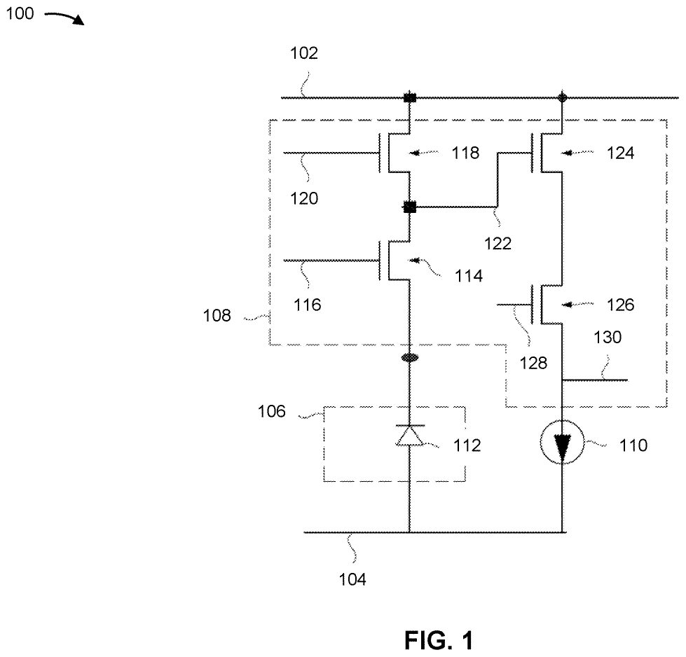

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor. The pixel sensor 100 may be electrically connected to a supply voltage (V_{dd}) 102 and an electrical ground 104.

The pixel sensor 100 includes a sensing region 106 that may be configured to sense and/or accumulate incident light (e.g., light directed toward the pixel sensor 100). The pixel sensor 100 also includes a control circuitry region 108. The control circuitry region 108 is electrically connected with the sensing region 106 and is configured to receive a photocurrent 110 that is generated by the sensing region 106. Moreover, the control circuitry region 108 is configured to transfer the photocurrent 110 from the sensing region 106 to downstream circuits such as amplifiers or analog-to-digital (AD) converters, among other examples.

The sensing region 106 includes a photodiode 112. The photodiode 112 may absorb and accumulate photons of the incident light, and may generate the photocurrent 110 based on absorbed photons. The magnitude of the photocurrent 110 is based on the amount of light collected in the photodiode 112. Thus, the accumulation of photons in the photodiode 112 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 112 is electrically connected with a source of a transfer gate 114 in the control circuitry region 108. The transfer gate 114 is configured to control the transfer of the photocurrent 110 from the photodiode 112. The photocurrent 110 is provided from the source of the transfer gate 114 to a drain of the transfer gate 114 based on selectively switching a gate of the transfer gate 114. The gate of the transfer gate 114 may be selectively switched by applying a transfer voltage (Vₜₓ) 116 to the transfer gate 114. In some implementations, the transfer voltage 116 being applied to the transfer gate 114 causes a conductive channel to form between the source and the drain of the transfer gate 114, which enables the photocurrent 110 to traverse along the conductive channel from the source to the drain. In some implementations, the transfer voltage 116 being removed from the transfer gate 114 (or the absence of the transfer voltage 116) causes the conductive channel to be removed such that the photocurrent 110 cannot pass from the source to the drain.

The control circuitry region 108 further includes a reset gate 118. The reset gate 118 is electrically connected to the supply voltage 102. The reset gate 118 may be controlled by a reset voltage (Vᵣₛₜ) 120. The transfer gate 114 and the reset gate 118 may be electrically coupled with a floating diffusion node 122. The reset voltage 120 may be applied to the reset gate 118 to pull the drain of the transfer gate 114 to a high voltage (e.g., to the supply voltage 102) to “reset” the floating diffusion node 122 (e.g., by draining any residual charge in the floating diffusion node 122) prior to activation of the transfer gate 114 to transfer the photocurrent 110 from the photodiode 112 to the floating diffusion node 122.

The photocurrent 110 may be used to apply a floating diffusion voltage (V_{fd}) to a source follower gate 124 of the control circuitry region 108. This permits the photocurrent 110 to be observed without removing or discharging the photocurrent 110 from the floating diffusion node 122. The reset gate 118 may instead be used to remove or discharge the photocurrent 110 from the floating diffusion node 122.

The source follower gate 124 functions as a high impedance amplifier for the pixel sensor 100. The source follower gate 124 provides a voltage to current conversion of the floating diffusion voltage. The output of the source follower gate 124 is electrically connected with a row select gate 126, which is configured to control the flow of the photocurrent 110 to external circuitry. The row select gate 126 is controlled by selectively applying a select voltage (V_{di}) 128 to the gate of the row select gate 126. This permits the photocurrent 110 to flow to an output 130 of the pixel sensor 100.

As indicated above, FIG. 1 is provided as an example. Other examples may differ from what is described with regard to FIG. 1.

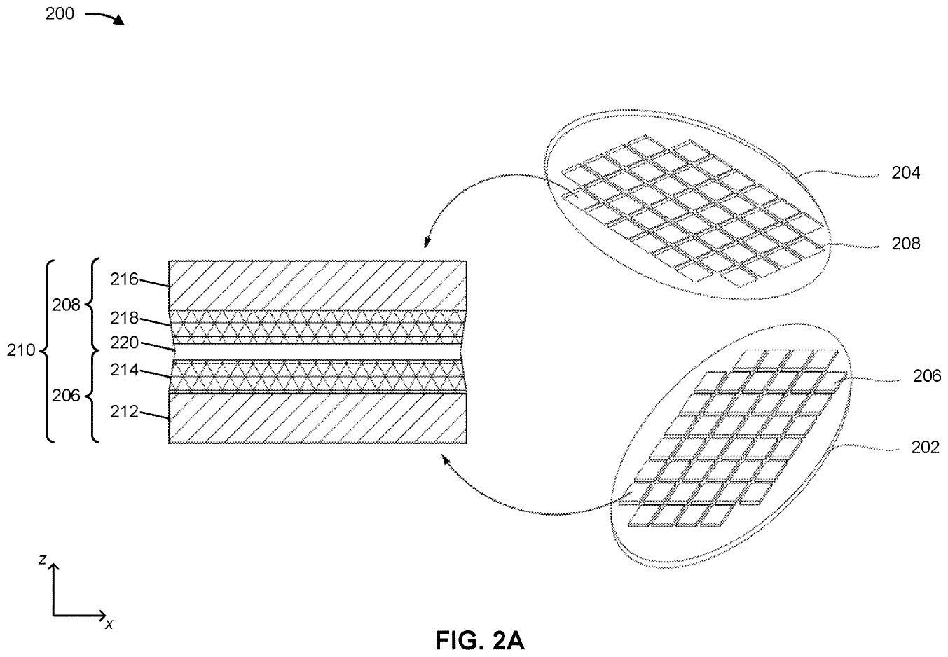

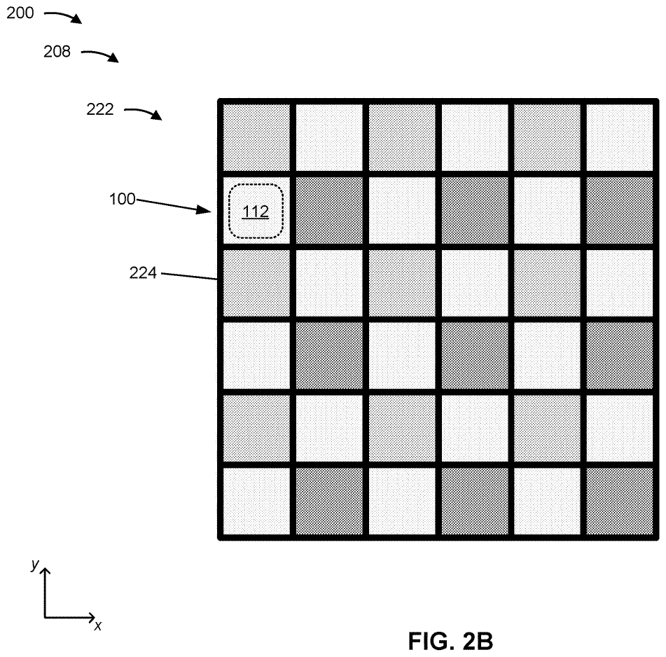

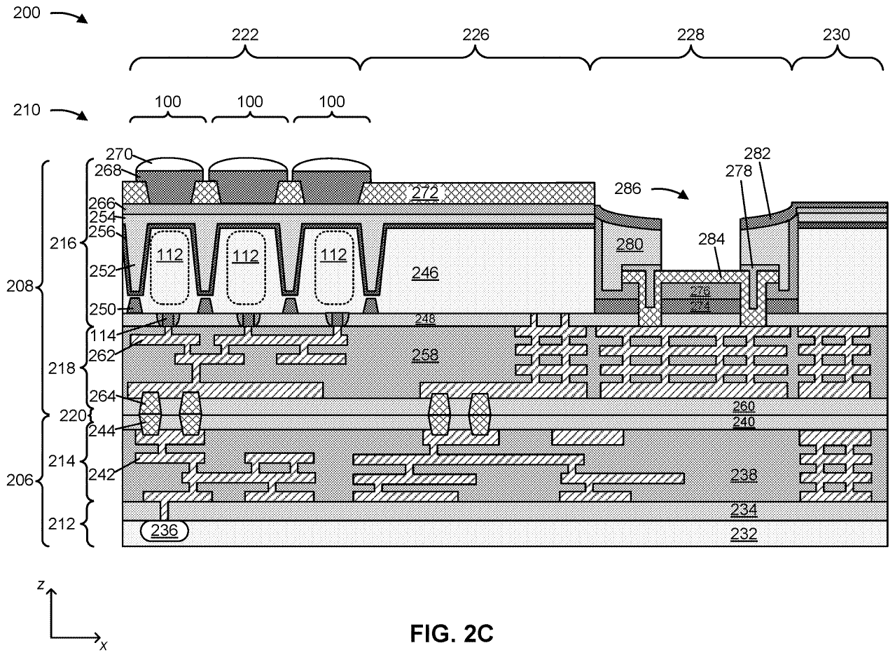

FIGS. 2A-2C are diagrams of examples 200 of an image sensor device described herein. As shown in FIG. 2A, an image sensor device may be formed by bonding a circuitry wafer 202 and a sensor wafer 204. For example, a bonding tool may be used to perform a bonding operation to bond the circuitry wafer 202 and the sensor wafer 204 using a metal-to-metal bonding technique, a dielectric-to-dielectric bonding technique, and/or another bonding technique. In the bonding operation, circuitry dies 206 on the circuitry wafer 202 are bonded with associated sensor dies 208 on the sensor wafer 204 to image sensor devices 210. The image sensor devices 210 are then diced and packaged. Other processing steps may be performed to form the image sensor devices 210.

Each image sensor device 210 includes a circuitry die 206 and a sensor die 208. The circuitry die 206 and the sensor die 208 may be stacked or vertically arranged in the image sensor device 210. The sensor die 208 includes a pixel sensor array that includes a plurality of pixel sensors 100, or portions of a plurality of pixel sensors 100. In particular, the pixel sensor array includes at least the sensing regions 106 (and thus, the photodiodes 112) of the pixel sensors 100. Accordingly, the sensor die 208 primarily is configured to sense photons of incident light and convert the photons to a photocurrent 110.

The circuitry die 206 includes circuitry that is configured to measure, manipulate, and/or otherwise use the photocurrent 110. Moreover, the circuitry die 206 includes at least a subset of the transistors of the control circuitry regions 108 of the pixel sensors 100. For example, the circuitry die 206 may include the row select gates 126 of the pixel sensors 100, the source follower gates 124 of the pixel sensor, and/or a combination thereof. This provides increased area on the sensor die 208 for the photodiodes 112, which enables the size of the photodiodes 112 to be increased to increase the sensitivity and/or overall performance of the light sensing performance of the pixel sensor, and/or enables the size of the pixel sensors 100 to be decreased while maintaining the same size for the photodiodes 112.

As further shown in FIG. 2A, the circuitry die 206 may include a device layer 212 and an interconnect layer 214. The device layer 212 may include the devices (e.g., transistors) of the circuitry die 206, and the interconnect layer 214 may include interconnects that enable signals and/or power to be provided to and/or from the devices in the device layer 212. The sensor die 208 may also include a device layer 216 and an interconnect layer 218. The device layer 216 may include portions of the pixel sensors 100, including the photodiodes 112, the transfer gates 114, and the floating diffusion nodes 122, among other examples. The interconnect layer 218 may include interconnects that enable signals and/or power to be provided to and/or from the device layer 216.

The circuitry die 206 and the sensor die 208 may be bonded at a bonding interface 220, which may be included between the interconnect layers 214 and 218, and/or may be included in a portion of the interconnect layers 214 and/or 218. The bonding interface 220 may include bonding pads, bonding vias, bonding dielectric layers, and/or other bonding structures.

FIG. 2B is a top-down view of an example pixel sensor array 222 included on a sensor die 208. The pixel sensor array 222 may be included on a sensor die 208 of an image sensor device 210. As shown in FIG. 2B, the pixel sensor array 222 may include a plurality of pixel sensors 100 (or portions of the plurality of plurality of pixel sensors 100). For example, the pixel sensor array 222 may include the photodiodes 112 of the pixel sensors 100. As further shown in FIG. 2B, the pixel sensors 100 may be arranged in a grid. In some implementations, the pixel sensors 100 are square-shaped (as shown in the example in FIG. 2B). In some implementations, the pixel sensors 100 include other shapes such as rectangle shapes, circle shapes, octagon shapes, diamond shapes, and/or other shapes.

In some implementations, the size of the pixel sensors 100 (e.g., the width or the diameter) of the pixel sensors 100 is approximately 1 micron. In some implementations, the size of the pixel sensors 100 (e.g., the width or the diameter) of the pixel sensors 100 is less than approximately 1 micron. For example, a width of one or more of the pixel sensors 100 may be included in a range of approximately 0.6 microns to approximately 0.7 microns. In these examples, the pixel sensors 100 may be referred to as sub-micron pixel sensors. Sub-micron pixel sensors may decrease the pixel sensor pitch (e.g., the distance between adjacent pixel sensors) in the pixel sensor array 222, which may enable increased pixel sensor density in the pixel sensor array 222 (which can increase the performance of the pixel sensor array 222). However, other values for the range of the size of the pixel sensors 100 are within the scope of the present disclosure.

Each pixel sensor 100 may be configured to sense a particular wavelength range of incident light associated with a particular color component of the incident light. For example, a pixel sensor 100 may be configured to sense a wavelength range associated with a red component of incident light, and may therefore be referred to as a red pixel sensor. As another example, a pixel sensor 100 may be configured to sense a wavelength range associated with a blue component of incident light, and may therefore be referred to as a blue pixel sensor. As another example, a pixel sensor 100 may be configured to sense a wavelength range associated with a green component of incident light, and may therefore be referred to as a green pixel sensor. In some implementations, a plurality of pixel sensors 100 are configured to sense a wavelength range associated with a near infrared (NIR) component of incident light, and may therefore be referred to as NIR pixel sensors. The NIR pixel sensors may be included in the pixel sensor array 222 to improve low-light performance of the image sensor device 210 and/or to enable night-vision functionality to be realized for the image sensor device 210.

As further shown in FIG. 2B, the photodiodes 112 of the pixel sensors 100 may be electrically and optically isolated by a metal grid structure 224 included in the pixel sensor array 222. The photodiodes 112 may be formed in a substrate of the sensor die 208, and the metal grid structure 224 may be included above the substrate. The metal grid structure 224 includes a plurality of intersecting metal lines around the perimeters of the pixel sensors 100. The metal grid structure 224 may be formed of tungsten (W) and/or another suitable metal or metal alloy. The metal grid structure 224 may be included in the pixel sensor array 222 to reduce optical cross-talk between the pixel sensors 100, which reduces color mixing between the pixel sensors 100.

FIG. 2C illustrates a cross-section view of an image sensor device 210. As shown in FIG. 2C, a circuitry die 206 and a sensor die 208 may be bonded at a bonding interface 220 such that the circuitry die 206 and the sensor die 208 are stacked or vertically arranged in a z-direction in the image sensor device 210. As further shown in FIG. 2C, the image sensor device 210 includes the pixel sensor array 222 (e.g., including the pixel sensors 100), a black level region (BLC) region 226 adjacent to (e.g., horizontally adjacent to) the pixel sensor array 222, a bonding pad region 228 adjacent to (e.g., horizontally adjacent to) the BLC region 226, and a seal ring region 230 adjacent to (e.g., horizontally adjacent to) the bonding pad region 228, among other examples.

As further shown in FIG. 2C, the image sensor device 210 includes a plurality of layers, such as the device layer 212 and the interconnect layer 214 of the circuitry die 206, and the device layer 216 and the interconnect layer 218 of the sensor die 208. The device layer 212 of the circuitry die 206 includes a substrate 232 and a dielectric layer 234 above the substrate 232. The substrate 232 may include silicon (Si) (e.g., a silicon substrate), a material including silicon, a III-V compound semiconductor material such as gallium arsenide (GaAs), a silicon on insulator (SOI), or another type of semiconductor material. The substrate 232 may include a semiconductor layer such as a silicon layer. The dielectric layer 234 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

Devices 236 may be included in and/or on the substrate 232 of the device layer 212. The devices 236 may include one or more application-specific integrated circuit (ASIC) devices, one or more system-on-chip (SOC) devices, one or more transistors, and/or one or more other components configured to measure the magnitude of a photocurrent 110 generated by the pixel sensors 100 to determine light intensity of incident light and/or to generate images and/or video (e.g., digital images, digital video).

The interconnect layer 214 of the circuitry die 206 may include a dielectric layer 238, a bonding layer 240, a plurality of interconnect structures 242 in the dielectric layer 238, and a plurality of bonding structures 244 in the bonding layer 240. The dielectric layer 238 may include one or more interlayer dielectric (ILD) layers, one or more intermetal dielectric (IMD) layers, and/or one or more etch stop layers (ESLs), among other examples. The dielectric layer 238 and the bonding layer 240 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 242 may each include conductive lines, trenches, vias, interconnects, metallization layers, and/or other types of electrically conductive structures that electrically connect the devices 236 to one or more other regions of the circuitry die 206 and/or to one or more regions of the sensor die 208, among other examples. The bonding structures 244 may each include bonding pads, bonding vias, and/or other types of bonding structures. The interconnect structures 242 and the bonding structures 244 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

The device layer 216 of the sensor die 208 includes a substrate 246 and a dielectric layer 248 below the substrate r 246. The substrate 246 may include silicon (Si) (e.g., a silicon substrate), a silicon layer or another type of semiconductor layer, a material including silicon, a III-V compound semiconductor material such as gallium arsenide (GaAs), an SOI, or another type of semiconductor material. The dielectric layer 248 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The photodiodes 112 of the pixel sensors 100 are included in the substrate 246 of the sensor die 208. The photodiodes 112 may each include one or more doped regions of substrate 246. The substrate 246 may be doped with a plurality of types of ions to form a p-n junction or a PIN junction (e.g., a junction between a p-type portion, an intrinsic (or undoped) type portion, and an n-type portion) corresponding to a photodiode 112. For example, the substrate 246 may be doped with an n-type dopant to form a first portion (e.g., an n-type portion) of a photodiode 112 and a p-type dopant to form a second portion (e.g., a p-type portion) of the photodiode 112. A photodiode 112 may be configured to absorb photons of incident light. The absorption of photons causes the photodiode 112 to accumulate a charge (a photocurrent 110) due to the photoelectric effect. Here, photons bombard the photodiode 112, which causes emission of electrons of the photodiode 112. The emission of electrons causes the formation of electron-hole pairs, where the electrons migrate toward the cathode of the photodiode 112 and the holes migrate toward the anode, which produces the photocurrent 110.

The photodiodes 112 may be electrically isolated and/or optically isolated from one another by one or more isolation structures in the substrate 246. Shallow trench isolation (STI) structures 250 extend into the substrate 246 from a bottom side of the substrate 246 (referred to as the front side of the substrate 246), and a deep trench isolation (DTI) structure 252 extends into the substrate 246 from a top side of the substrate 246 (referred to as the back side of the substrate 246) over the STI structures 250. The combination of the STI structures 250 and the DTI structure 252 in the substrate 246 surround the pixel sensors 100 in the substrate 246 and provide the electrically isolation and/or optically isolation for the pixel sensors 100 in the substrate 246.

The STI structures 250 may include one or more dielectric materials, such as a silicon oxide (SiOₓ), a silicon nitride (SiₓN_{y}), and/or a silicon oxynitride (SiON), among other examples. The DTI structure 252 may include elongated structures of dielectric material 254 and a dielectric liner 256 between the dielectric material 254 and the substrate 246. The DTI structure 252 extends along the sides of the photodiodes 112 and conforms to the top view shape of the metal grid structure 224 illustrated in FIG. 2B. The dielectric material 254 may also be included on the top side of the substrate 246 as a buffer layer. The dielectric liner 256 may be included on sidewalls and on a bottom surface of the DTI structure 252, and may be included as an antireflective coating (ARC) and/or to further facilitate electrical and/or optical isolation of the pixel sensors 100. In some implementations, the dielectric material 254 includes a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. In some implementations, the dielectric liner 256 may include a high-k dielectric material such as a silicon nitride (SiₓN_{y}), a hafnium oxide (HfOₓ), and/or another high-k dielectric material.

Transfer gates 114 of the pixel sensors 100 are included in the dielectric layer 248 and on the bottom side of the substrate 246. The transfer gates 114 are electrically connected to the interconnect layer 218, which enables inputs (e.g., gate voltages) to be provided to the transfer gates 114 to control the flow of photocurrents 110 from the photodiodes 112 to floating diffusion nodes 122 (not shown) of pixel sensors 100.

The interconnect layer 218 may include a dielectric layer 258, a bonding layer 260, a plurality of interconnect structures 262 in the dielectric layer 258, and a plurality of bonding structures 264 in the bonding layer 260. The dielectric layer 258 may include one or more ILD layers, one or more IMD layers, and/or one or more ESLs, among other examples. The dielectric layer 258 and the bonding layer 260 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 262 may each include conductive lines, trenches, vias, interconnects, metallization layers, and/or other types of electrically conductive structures that electrically connect the transfer gates 114 to one or more other regions of the sensor die 208 and/or to one or more regions of the circuitry die 206, among other examples. The bonding structures 264 may each include bonding pads, bonding vias, and/or other types of bonding structures. The interconnect structures 262 and the bonding structures 264 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

At the bonding interface 220, the bonding layers 240 and 260 may be bonded together (e.g., in a dielectric-to-dielectric bond), and the bonding structures 244 and 264 may be bonded together (e.g., in a metal-to-metal bond). Signals and/or power may be provided between the circuitry die 206 and the sensor die 208 through the bonding structures 244 and 264.

Above the top side of the substrate 246, a passivation layer 266 may be included on the buffer layer, and the metal grid structure 224 may be included above the passivation layer 266. The passivation layer 266 may include an oxide material such as a silicon oxide (SiOₓ). Additionally and/or alternatively, a silicon nitride (SiNₓ), a silicon carbide (SiCₓ), or a mixture thereof, such as a silicon carbon nitride (SiCN), a silicon oxynitride (SiON), or another dielectric material is used for the passivation layer 266.

As shown in FIG. 2C, sections of the metal grid structure 224 may have an approximately trapezoidal cross-section shape or profile. Additionally and/or alternatively, sections of the metal grid structure 224 may have an approximately square-shaped cross-sectional profile. The sections of the metal grid structure 224 may be located over the DTI structure 252 and may be formed around the perimeter of the photodiodes 112 of the pixel sensors 100. Openings in the metal grid structure 224 are included above the photodiodes 112 to enable incident light to pass through the metal grid structure 224 and to the photodiodes 112. The metal grid structure 224 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

Color filter regions 268 of the pixel sensors 100 be included in the openings in the metal grid structure 224. The color filter regions 268 may be included above the photodiodes 112 of the pixel sensors 100. The color filter regions 268 may be included above the photodiodes 112. Each color filter region 268 may be configured to filter incident light to allow a particular wavelength of the incident light to pass to a photodiode 112. For example, a color filter region 268 may filter incident light to allow red light to pass through the color filter region 268 to an associated photodiode 112. As another example, a color filter region 268 may filter incident light to allow green light to pass through the color filter region 268 to an associated photodiode 112. As another example, a color filter region 268 may filter incident light to allow blue light to pass through the color filter region 268 to an associated photodiode 112.

A blue color filter region 268 may permit the component of incident light near a 450 nanometer wavelength to pass through and may block other wavelengths from passing. A green color filter region 268 may permit the component of incident light near a 550 nanometer wavelength to pass and may block other wavelengths from passing. A red color filter region 268 may permit the component of incident light near a 650 nanometer wavelength to pass and may block other wavelengths from passing. A yellow color filter region 268 may permit the component of incident light near a 580 nanometer wavelength to pass and may block other wavelengths from passing.

In some implementations, a color filter region 268 may be non-discriminating or non-filtering, which may define a white pixel sensor. A non-discriminating or non-filtering color filter region 268 may include a material that permits all wavelengths of light to pass into the associated photodiode 112 (e.g., for purposes of determining overall brightness to increase light sensitivity for the image sensor). In some implementations, a color filter region 268 may be a an NIR bandpass color filter region 268, which may define an NIR pixel sensor. An NIR bandpass color filter region 268 may include a material that permits the portion of incident light in an NIR wavelength range to pass to an associated photodiode 112 while blocking visible light from passing.

Micro-lenses 270 may be included over and/or on the color filter regions 268. The micro-lenses 270 may include a respective micro-lens for each of the pixel sensors 100. A micro-lens may be formed to focus incident light toward a photodiode 112 of an associated pixel sensor 100.

As further shown in FIG. 2C, a metal layer 272 may be included above the substrate 246 in the BLC region 226 of the substrate 246. The metal layer 272 may be included as a light-blocking layer to prevent incident light from entering the portion of substrate 246 in the BLC region 226. The portion of substrate 246 in the BLC region 226 is thus a sensing region that is kept “dark” so that dark current measurements may be performed in the BLC region 226. A dark current measurement may be performed to measure the amount of charge (dark current) in the substrate 246 that is generated from sources other than incident light (e.g., from thermal energy in the substrate 246) so that the dark current measurement may be used for black level correction (or black level calibration) for the pixel sensor array 222.

As further shown in FIG. 2C, the bonding pad region 228 may include a plurality of dielectric layers 274, 276, 278, 280, and 282 that electrically isolate a bonding pad structure 284. The bonding pad structure 284 is electrically coupled and/or physically coupled with one or more of the interconnect structures 262 in the interconnect layer 218 of the sensor die 208. A bonding pad opening 286 is included above the bonding pad structure 284 to enable an external electrical connection to be formed to the bonding pad structure 284.

The plurality of dielectric layers 274, 276, 278, 280, and 282 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples. The bonding pad structure 284 may include a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

The seal ring region 230 includes a plurality of stacked interconnect structures 242 in the interconnect layer 214 and a plurality of stacked interconnect structures 262 in the interconnect layer 218 to seal the structures and layers of the image sensor device 210 to prevent ingress of humidity and other contaminants, as well as to provide structural rigidity to the image sensor device 210.

As indicated above, FIGS. 2A-2C are provided as examples. Other examples may differ from what is described with regard to FIGS. 2A-2C.

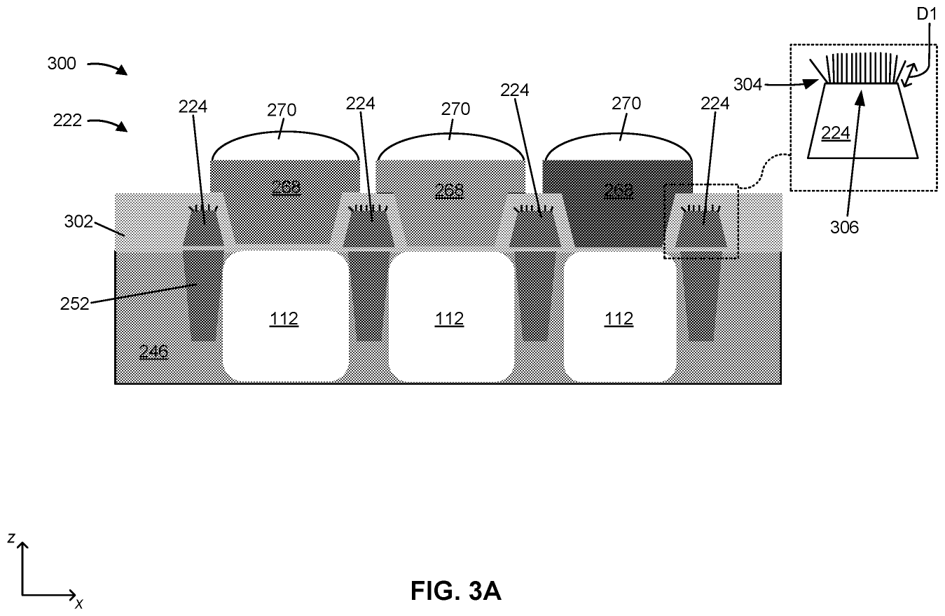

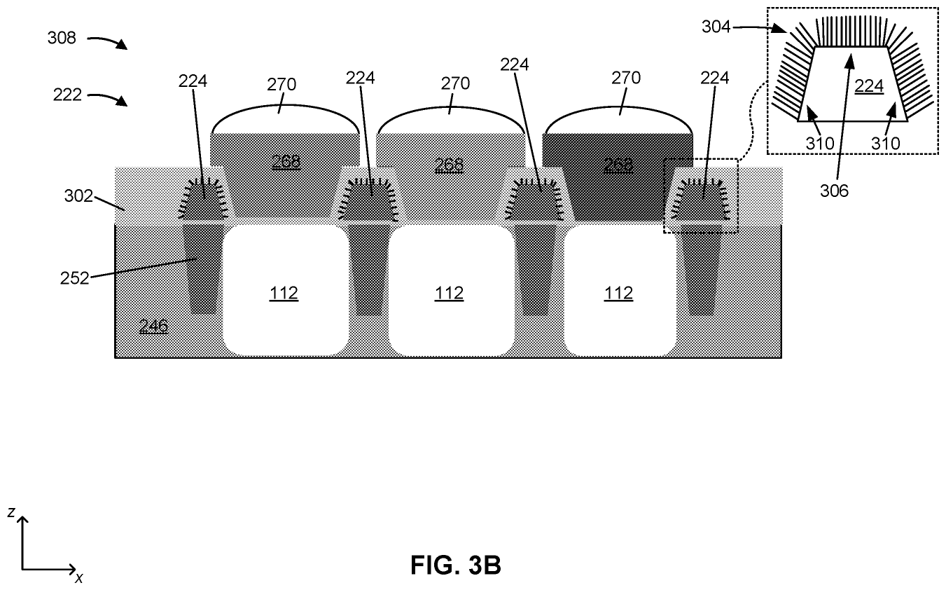

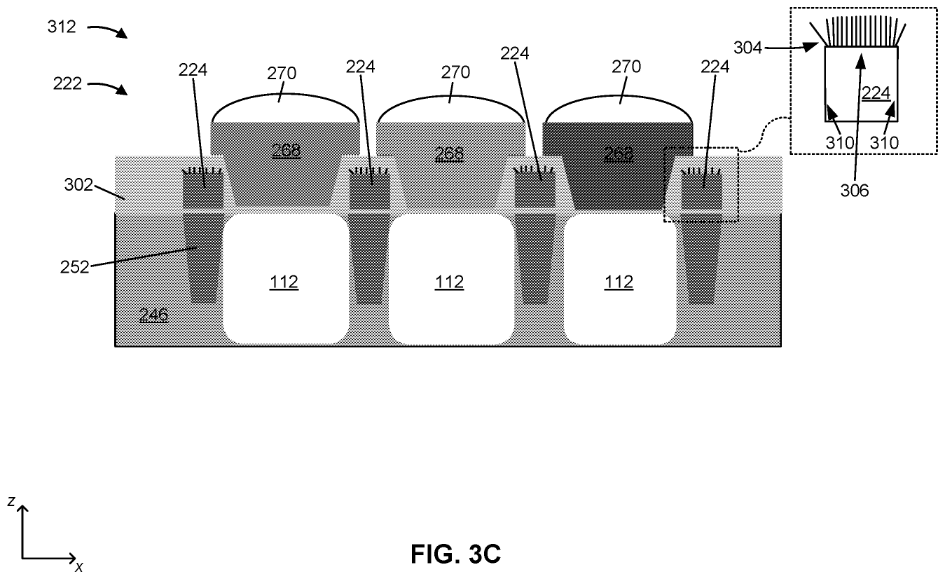

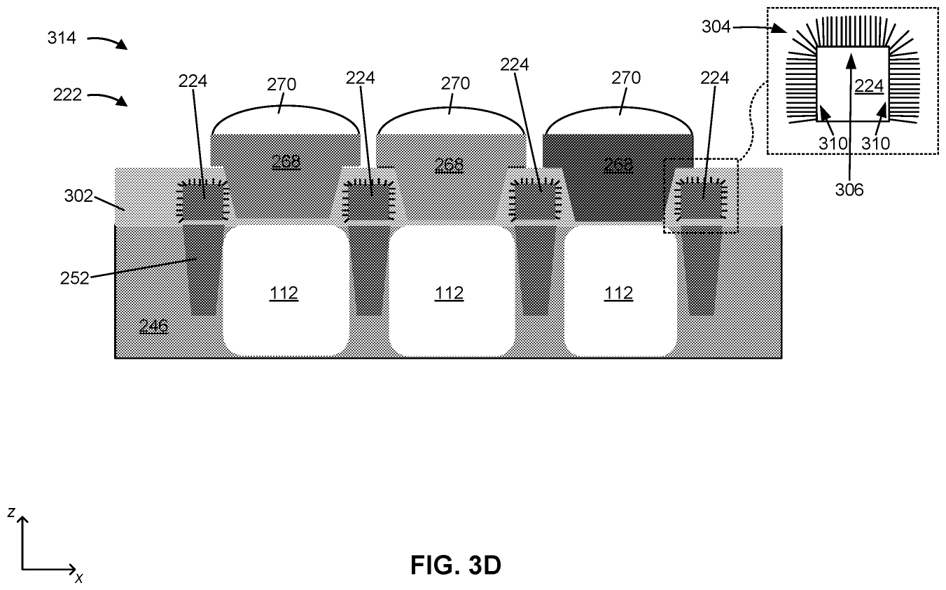

FIGS. 3A-3D are diagrams of examples of pixel sensor arrays 222 of a sensor die 208 described herein. FIGS. 3A-3D illustrate cross-section views of the examples of the pixel sensor arrays 222. The examples illustrated in FIGS. 3A-3D each include an example implementation of an antireflection structure for the metal grid structure 224 of the pixel sensor arrays 222. Each example implementation of the antireflection structures described herein may be included in an associated pixel sensor array 222 to reduce, minimize, and/or prevent incident light from being reflected away from a pixel sensor 100 toward another pixel sensor 100. Thus, each example implementation of the antireflection structures described herein may reduce, minimize, and/or prevent optical crosstalk between the pixel sensors 100 of the associated pixel sensor array 222. One or more of the examples of the pixel sensor arrays 222 of FIGS. 3A-3D may be included in a sensor die 208 of an image sensor device 210 illustrated and described in connection with FIGS. 2A-2C.

As shown in FIG. 3A, an example 300 of a pixel sensor array 222 includes a plurality of pixel sensors 100. The pixel sensors 100 each include a photodiode 112 in the substrate 246 of the sensor die 208. A DTI structure 252 is included around the photodiodes 112 in the substrate 246, and a metal grid structure 224 is included on the substrate 246 above the DTI structure 252. The metal grid structure 224 extends above the substrate 246 and surrounds the photodiodes 112. Color filter regions 268 are included between the openings of the metal grid structure 224, and micro-lenses 270 are included on the color filter regions. A passivation layer 302 may additionally be included on the metal grid structure 224, or may be omitted.

As further shown in the example 300, nanostructures 304 are included on top surfaces 306 of the metal grid structure 224. The nanostructures 304 may include nanotubes, nanowires, and/or another type of nanostructures that extend from the top surfaces 306 of the metal grid structure 224. The nanostructures 304 may be formed of carbon (C) and/or another suitable material. The nanostructures 304 may reduce optical crosstalk in the pixel sensor array 222 in that the nanostructures 304 may absorb photons of incident light that might otherwise reflect off of the top surfaces 306 of the metal grid structure 224.

A length of the nanostructures 304 (indicated in FIG. 3A as dimension D1) may be included in a range of approximately 80 nanometers to approximately 1000 nanometers. If the length of the nanostructures 304 is less than approximately 80 nanometers, the nanostructures 304 may not provide sufficient optical absorption to reduce or prevent optical crosstalk, whereas the nanostructures 304 may reduce absorption of photons in the photodiodes 112 (which may reduce the quantum efficiency of the pixel sensors 100) if the length of the nanostructures 304 is greater than approximately 1000 nanometers. If the length of the nanostructures 304 is included in the range of approximately 80 nanometers to approximately 1000 nanometers, the nanostructures 304 may provide sufficient optical absorption to reduce or prevent optical crosstalk while enabling a high quantum efficiency to be achieved for the pixel sensors 100. However, other values for the length of the nanostructures 304, and ranges other than approximately 80 nanometers to approximately 1000 nanometers, are within the scope of the present disclosure.

The nanostructures 304 may extend in a direction that is approximately perpendicular to the top surfaces 306 of the metal grid structure 224. Additionally and/or alternatively, at least a subset of the nanostructures 304 may extend in a direction that is angled (e.g., angled at approximately 60 degrees, angled at approximately 75 degrees) relative to the top surfaces 306 of the metal grid structure 224.

As further shown in FIG. 3A, the metal grid structures 224 in the example 300 of the pixel sensor array 222 may have an approximately trapezoidal cross-section shape or profile. For example, a cross-sectional width of the top surface 306 of the metal grid structure 224 may be less than a cross-sectional width of a bottom surface of the metal grid structure 224. Thus, the cross-sectional width increases from the top surface 306 to the bottom surface for the metal grid structure 224.

FIG. 3B illustrates an example 308 of a pixel sensor array 222, which is similar to the example 300 of the pixel sensor array 222 except that the example 308 of the pixel sensor array 222 further includes nanostructures 304 on sidewalls 310 of the metal grid structure 224. Thus, the nanostructures 304 are included on the top surfaces 306 and on the sidewalls 310 of the metal grid structure 224. The nanostructures 304 may provide further optical crosstalk reduction by absorbing photons of incident light that are directed toward the sidewalls 310 of the metal grid structure 224.

FIG. 3C illustrates an example 312 of a pixel sensor array 222, which is similar to the example 300 of the pixel sensor array 222 except that the metal grid structure 224 in the example 312 of the pixel sensor array 222 has a square-shaped cross-section shape or profile. Thus, the sidewalls 310 of the metal grid structure 224 are approximately perpendicular to the top surfaces 306 of the metal grid structure 224.

FIG. 3D illustrates an example 314 of a pixel sensor array 222, which is similar to the example 312 of the pixel sensor array 222 except that the example 314 of the pixel sensor array 222 further includes nanostructures 304 on the sidewalls 310 of the metal grid structure 224. Thus, the nanostructures 304 are included on the top surfaces 306 and on the sidewalls 310 of the metal grid structure 224, where the sidewalls 310 are approximately perpendicular to the top surfaces 306. The nanostructures 304 may provide further optical crosstalk reduction by absorbing photons of incident light that are directed toward the sidewalls 310 of the metal grid structure 224.

As indicated above, FIGS. 3A-3D is provided as examples. Other examples may differ from what is described with regard to FIGS. 3A-3D.

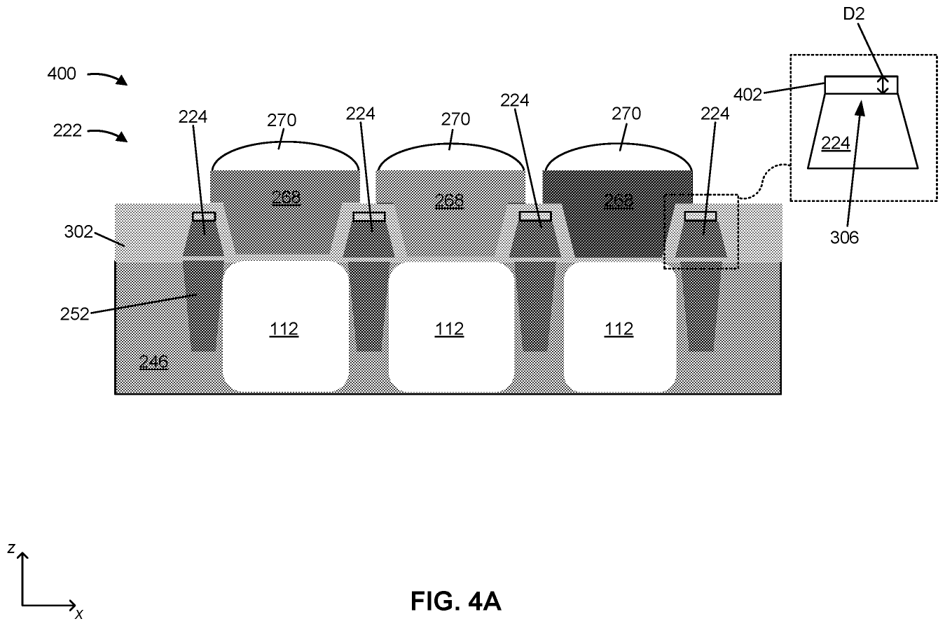

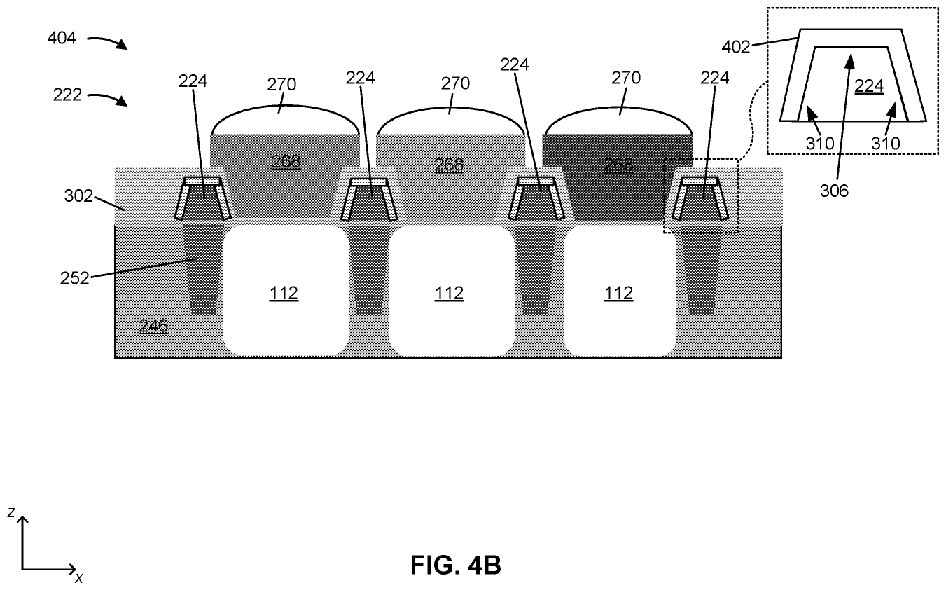

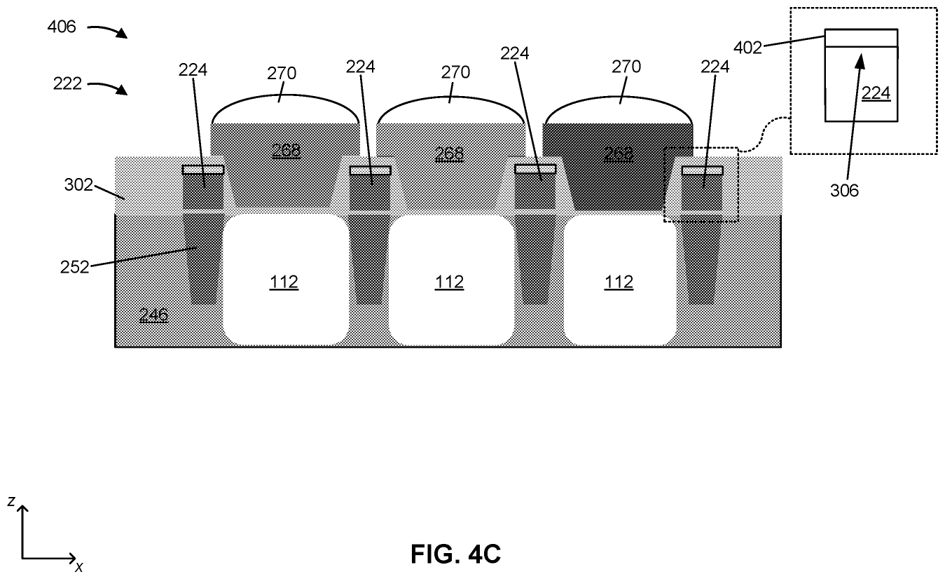

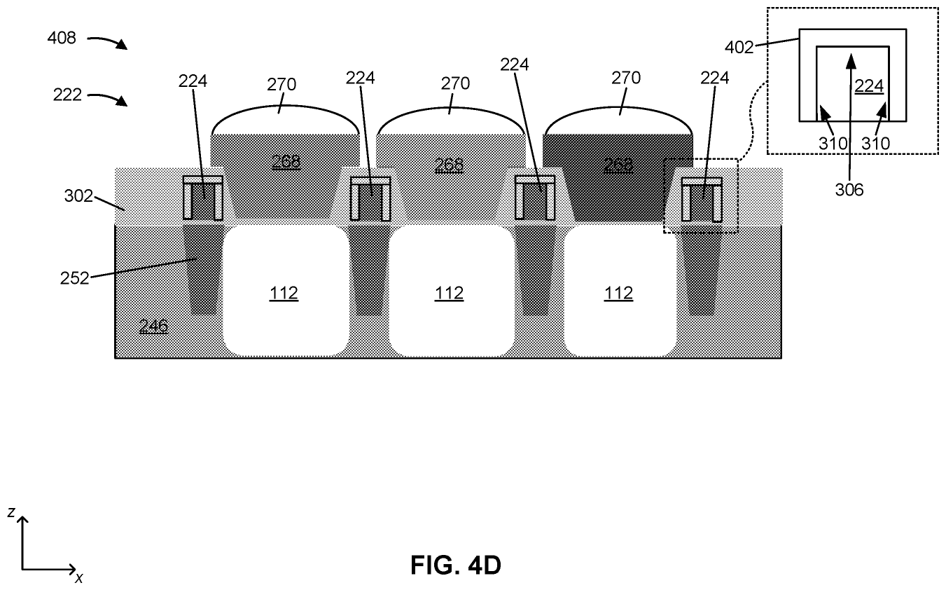

FIGS. 4A-4D are diagrams of examples of pixel sensor arrays 222 of a sensor die 208 described herein. FIGS. 4A-4D illustrate cross-section views of the examples of the pixel sensor arrays 222. The examples illustrated in FIGS. 4A-4D each include an example implementation of an antireflection structure for the metal grid structure 224 of the pixel sensor arrays 222. Each example implementation of the antireflection structures described herein may be included in an associated pixel sensor array 222 to reduce, minimize, and/or prevent incident light from being reflected away from a pixel sensor 100 toward another pixel sensor 100. Thus, each example implementation of the antireflection structures described herein may reduce, minimize, and/or prevent optical crosstalk between the pixel sensors 100 of the associated pixel sensor array 222. One or more of the examples of the pixel sensor arrays 222 of FIGS. 4A-4D may be included in a sensor die 208 of an image sensor device 210 illustrated and described in connection with FIGS. 2A-2C.

As shown in FIG. 4A, an example 400 of a pixel sensor array 222 includes a plurality of pixel sensors 100. The pixel sensors 100 each include a photodiode 112 in the substrate 246 of the sensor die 208. A DTI structure 252 is included around the photodiodes 112 in the substrate 246, and a metal grid structure 224 is included on the substrate 246 above the DTI structure 252. The metal grid structure 224 extends above the substrate 246 and surrounds the photodiodes 112. Color filter regions 268 are included between the openings of the metal grid structure 224, and micro-lenses 270 are included on the color filter regions. A passivation layer 302 may additionally be included on the metal grid structure 224, or may be omitted.

As further shown in the example 400, antireflective layers 402 are included on the top surfaces 306 of the metal grid structure 224. The antireflective layers 402 may each include a layer of antireflective material that absorbs photons of incident light. The layer of antireflective material may have one or more properties that, when included on the metal grid structure 224, result in cancelation of a broad range of wavelengths of incident light. Examples of such properties include refractive index, optical band gap, and/or thickness, among other examples. The properties of the layer of antireflective material may result in formation of destructive waves that are opposing and out of phase of the incident light, and these destructive waves cancel the incident light, which prevents or reduces the incident light from being reflected off of the metal grid structure 224. Thus, the antireflective material may be selected based on the material used for the metal grid structure 224. For example, the antireflective material may be selected such that the refractive index; optical band gap; and/or another property of the antireflective material, in combination with the refractive index; optical band gap; and/or another property of the metal material of the metal grid structure, results in formation of destructive waves that cancel the incident light. Examples of such antireflective materials include zinc oxide (ZnO), aluminum-doped zinc oxide (Al:ZnO or AZO), and/or aluminum oxide (AlₓO_{y} such as Al₃O₄), among other examples.

A thickness of the antireflective layers 402 (indicated in FIG. 4A as dimension D2) may be included in a range of approximately 50 nanometers to approximately 200 nanometers. If the thickness of the antireflective layers 402 is less than approximately 50 nanometers or greater than approximately 200 nanometers, the properties of the antireflective layers 402 may not combine with the properties of the metal material of the metal grid structure 224 to cancel out incident light to reduce or prevent optical crosstalk. If the thickness of the antireflective layers 402 is included in the range of approximately 50 nanometers to approximately 200 nanometers, the properties of the antireflective layers 402 may combine with the properties of the metal material of the metal grid structure 224 to cancel out incident light to reduce or prevent optical crosstalk. However, other values for the thickness of the antireflective layers 402, and ranges other than approximately 50 nanometers to approximately 200 nanometers, are within the scope of the present disclosure.

As further shown in FIG. 4A, the metal grid structures 224 in the example 400 of the pixel sensor array 222 may have an approximately trapezoidal cross-section shape or profile. For example, a cross-sectional width of the top surface 306 of the metal grid structure 224 may be less than a cross-sectional width of a bottom surface of the metal grid structure 224. Thus, the cross-sectional width increases from the top surface 306 to the bottom surface for the metal grid structure 224.

FIG. 4B illustrates an example 404 of a pixel sensor array 222, which is similar to the example 400 of the pixel sensor array 222 except that the antireflective layers 402 are included on the sidewalls 310 of the metal grid structure 224 in the example 404 of the pixel sensor array 222. Thus, the antireflective layers 402 are included on the top surfaces 306 and on the sidewalls 310 of the metal grid structure 224. The antireflective layers 402 may provide further optical crosstalk reduction by canceling out reflections of incident light that might otherwise reflect off of the sidewalls 310 of the metal grid structure 224.

FIG. 4C illustrates an example 406 of a pixel sensor array 222, which is similar to the example 400 of the pixel sensor array 222 except that the metal grid structure 224 in the example 406 of the pixel sensor array 222 has a square-shaped cross-section shape or profile. Thus, the sidewalls 310 of the metal grid structure 224 are approximately perpendicular to the top surfaces 306 of the metal grid structure 224.

FIG. 4D illustrates an example 408 of a pixel sensor array 222, which is similar to the example 406 of the pixel sensor array 222 except that the antireflective layers 402 are included on the sidewalls 310 of the metal grid structure 224 in the example 404 of the pixel sensor array 222. Thus, the antireflective layers 402 are included on the top surfaces 306 and on the sidewalls 310 of the metal grid structure 224, where the sidewalls 310 are approximately perpendicular to the top surfaces 306. The antireflective layers 402 may provide further optical crosstalk reduction by canceling out reflections of incident light that might otherwise reflect off of the sidewalls 310 of the metal grid structure 224.

As indicated above, FIGS. 4A-4D is provided as examples. Other examples may differ from what is described with regard to FIGS. 4A-4D.

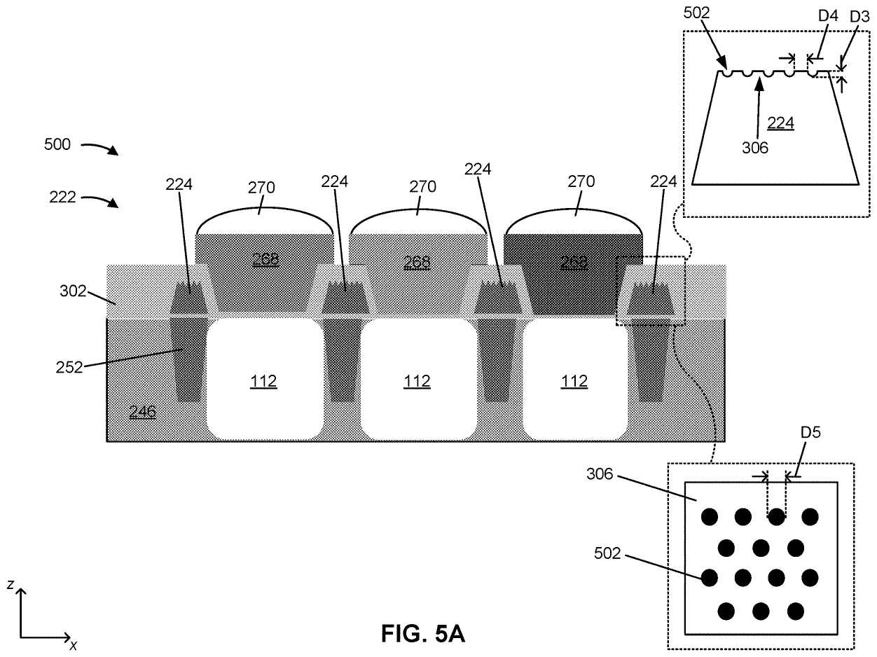

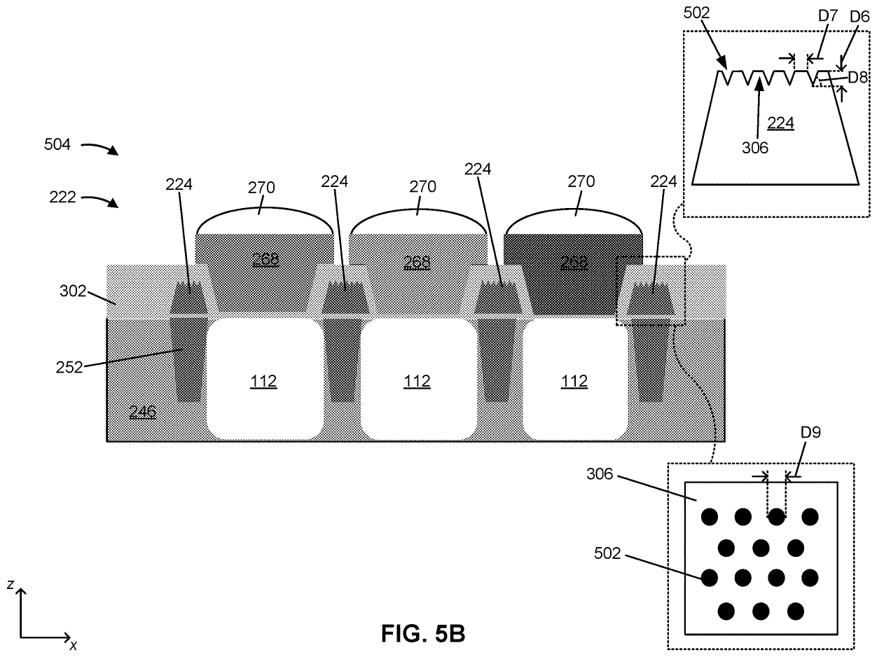

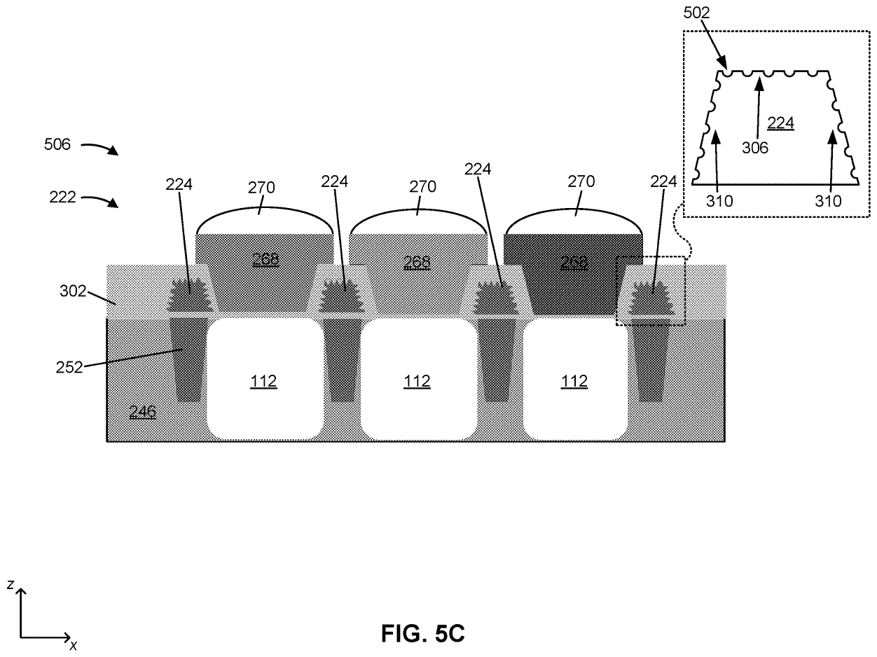

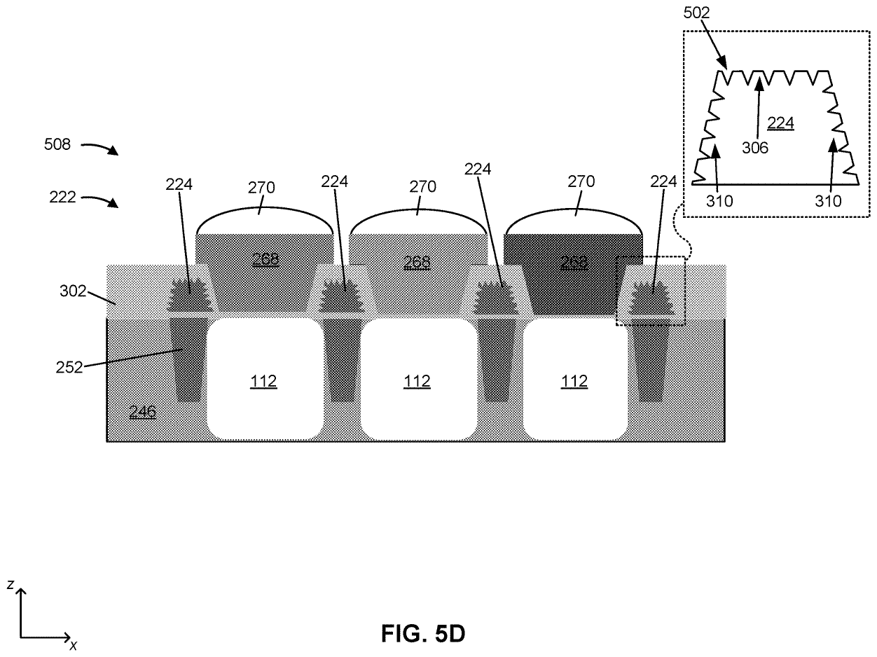

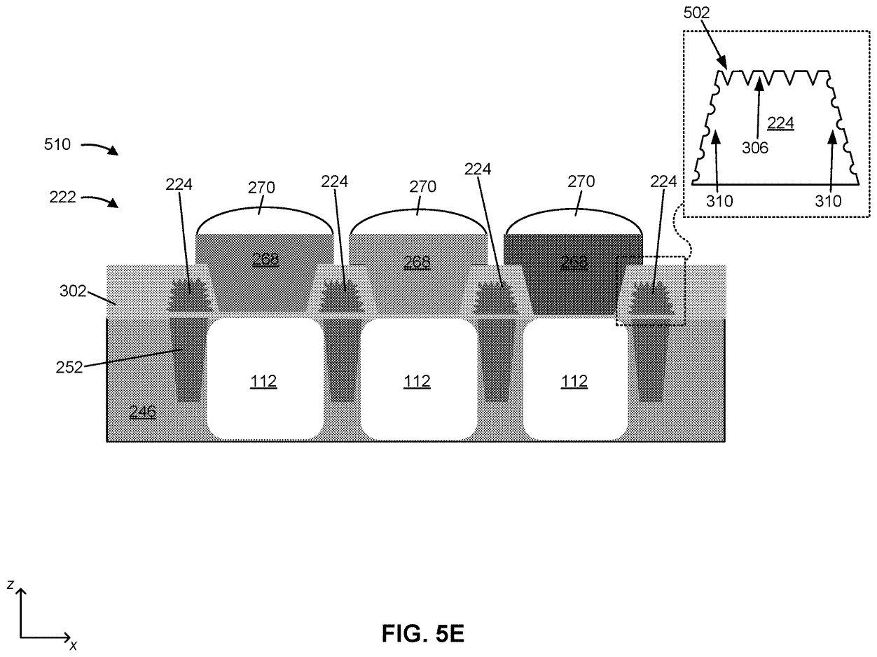

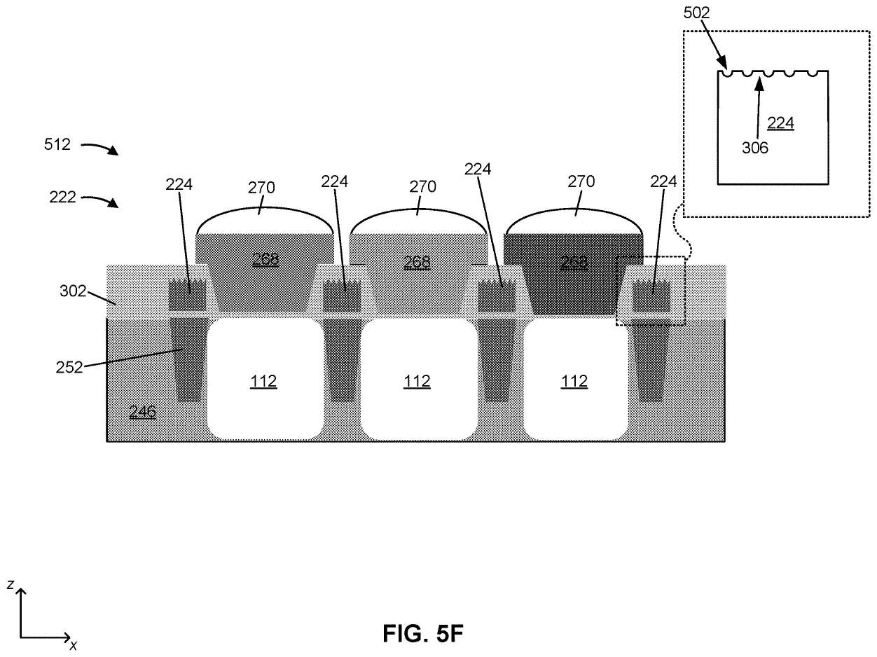

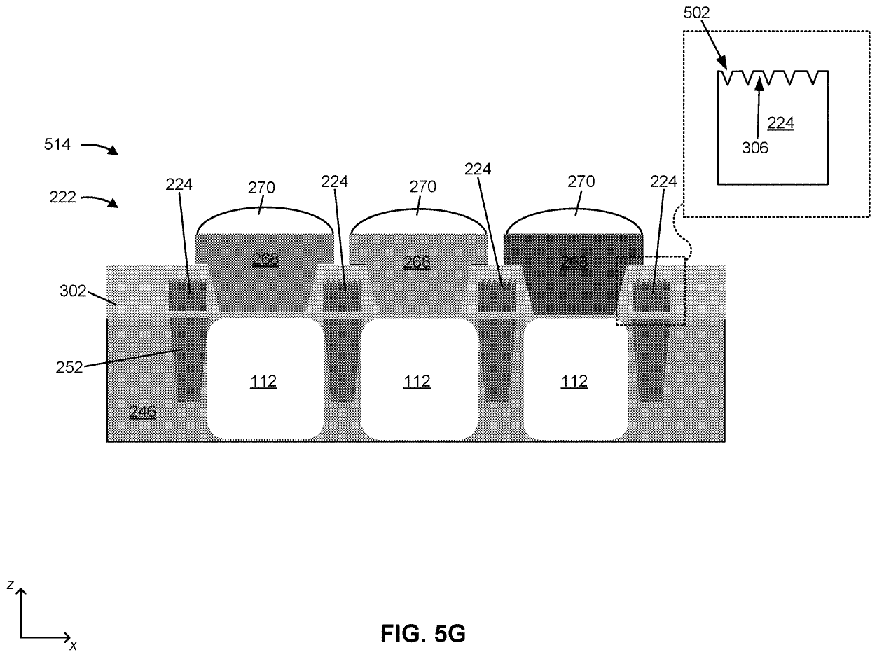

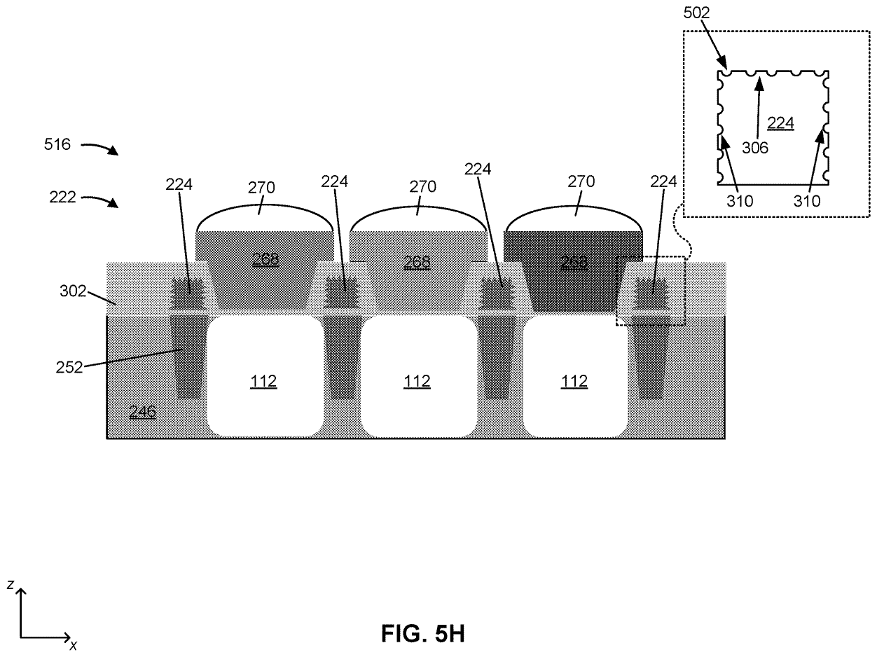

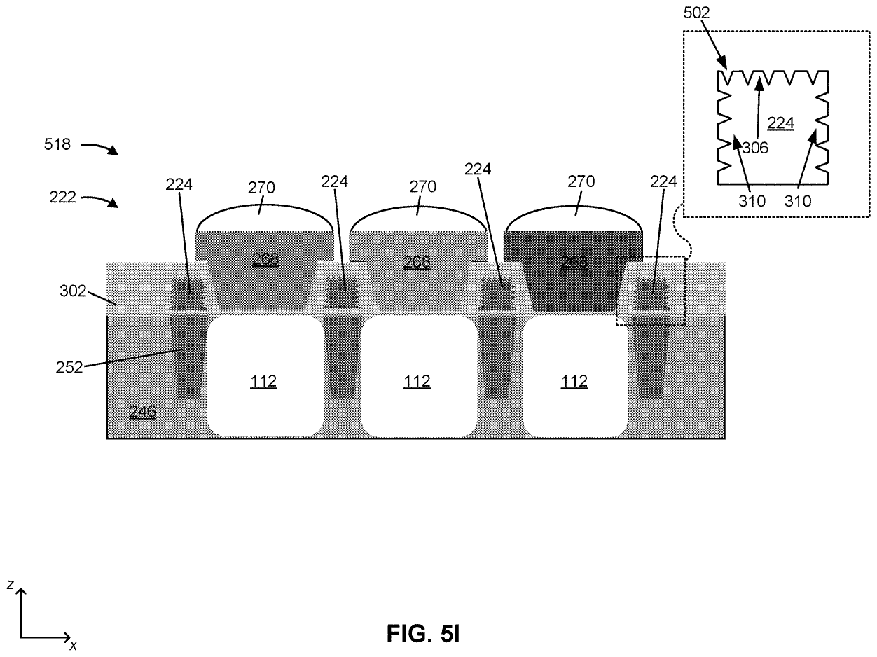

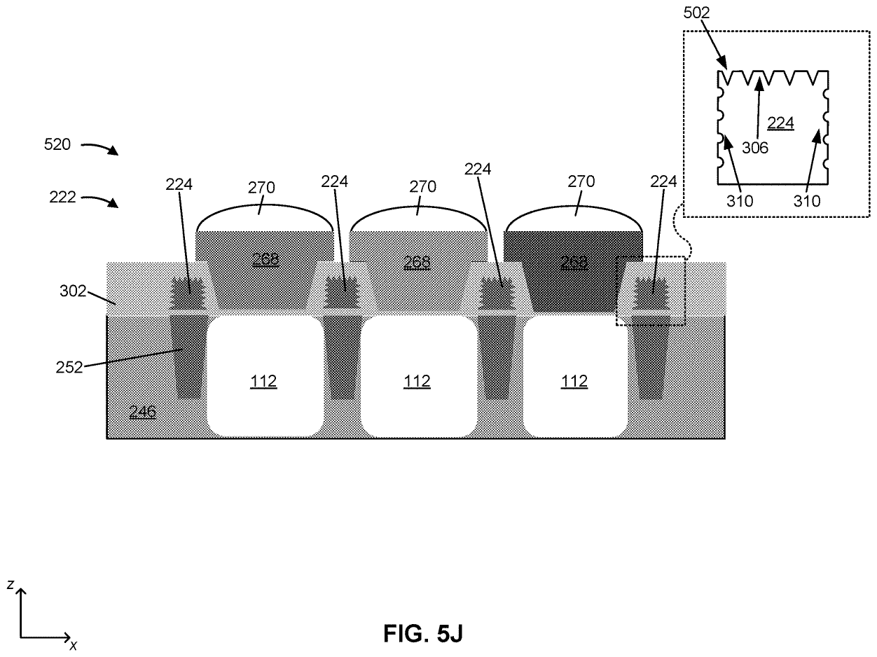

FIGS. 5A-5J are diagrams of examples of pixel sensor arrays 222 of a sensor die 208 described herein. FIGS. 5A-5J illustrate cross-section views of the examples of the pixel sensor arrays 222. The examples illustrated in FIGS. 5A-5J each include an example implementation of an antireflection structure for the metal grid structure 224 of the pixel sensor arrays 222. Each example implementation of the antireflection structures described herein may be included in an associated pixel sensor array 222 to reduce, minimize, and/or prevent incident light from being reflected away from a pixel sensor 100 toward another pixel sensor 100. Thus, each example implementation of the antireflection structures described herein may reduce, minimize, and/or prevent optical crosstalk between the pixel sensors 100 of the associated pixel sensor array 222. One or more of the examples of the pixel sensor arrays 222 of FIGS. 5A-5J may be included in a sensor die 208 of an image sensor device 210 illustrated and described in connection with FIGS. 2A-2C.

As shown in FIG. 5A, an example 500 of a pixel sensor array 222 includes a plurality of pixel sensors 100. The pixel sensors 100 each include a photodiode 112 in the substrate 246 of the sensor die 208. A DTI structure 252 is included around the photodiodes 112 in the substrate 246, and a metal grid structure 224 is included on the substrate er 246 above the DTI structure 252. The metal grid structure 224 extends above the substrate 246 and surrounds the photodiodes 112. Color filter regions 268 are included between the openings of the metal grid structure 224, and micro-lenses 270 are included on the color filter regions. A passivation layer 302 may additionally be included on the metal grid structure 224, or may be omitted.

As further shown in the example 500, cavities 502 are included in the top surfaces 306 of the metal grid structure 224 as the antireflection structures. The cavities 502 result in the top surfaces 306 of the metal grid structure 224 having a plurality of concave surfaces (or a plurality of recessed surfaces). The cavities 502 may be spaced apart from each other in the top surfaces 306 and may each have an approximately curved, rounded, and/or semi-circular cross-sectional profile. The curved or rounded surfaces of the cavities 502 scatter photons of incident light. Scattering the photons of incident light around a photodiode 112 causes the incident light to be directed in multiple directions off of the top surfaces 306 of the metal grid structure 224, thereby reducing the concentration of photons reflected toward other photodiodes 112, and thereby reducing optical crosstalk in the pixel sensor array 222.

The cavities 502 may have one or more dimensions, such as a depth (illustrated in FIG. 5A as dimension D3), a spacing between adjacent cavities 502 (illustrated in FIG. 5A as dimension D4), and/or a width (illustrated in FIG. 5A as dimension D5), among other examples. One or more dimensions of the cavities 502, the quantity of cavities 502, and/or another parameter of the cavities 502 may be selected to reduce, minimize, and/or prevent optical crosstalk from resulting from reflections of incident light off of the metal grid structure 224. The one or more dimensions of the cavities 502, the quantity of cavities 502, and/or another parameter of the cavities 502 may be selected based on a size of the pixel sensors 100 (e.g., a width of the pixel sensors 100, based on a wavelength or wavelengths of incident light that is to be sensed by the pixel sensor array 222, spacing between adjacent pixel sensors 100, and/or another parameter).

In some implementations, the depth of a cavity 502 (dimension D3) is included in a range of approximately 1 nanometer to approximately 10 nanometers. However, other values for the range are within the scope of the present disclosure. In some implementations, the spacing between adjacent cavities 502 (dimension D4) is included in a range of approximately 1 nanometer to approximately 5 nanometers. However, other values for the range are within the scope of the present disclosure. In some implementations, the width of a cavity 502 (dimension D5) is included in a range of approximately 1 nanometer to approximately 50 nanometers. However, other values for the range are within the scope of the present disclosure.

As further shown in FIG. 5A, the metal grid structures 224 in the example 500 of the pixel sensor array 222 may have an approximately trapezoidal cross-section shape or profile. For example, a cross-sectional width of the top surface 306 of the metal grid structure 224 may be less than a cross-sectional width of a bottom surface of the metal grid structure 224. Thus, the cross-sectional width increases from the top surface 306 to the bottom surface for the metal grid structure 224.

FIG. 5B illustrates an example 504 of a pixel sensor array 222, which is similar to the example 500 of the pixel sensor array 222 except that the cavities 502 have an approximately V-shaped (or triangular) cross-sectional profile in the example 504 of the pixel sensor array 222. The cavities 502 in the example 504 may have one or more dimensions, such as a depth (illustrated in FIG. 5B as dimension D6), a spacing between adjacent cavities 502 (illustrated in FIG. 5B as dimension D7), a sidewall angle relative to a bottom surface of the metal grid structure 224 (illustrated in FIG. 5B as dimension D8), and/or a width (illustrated in FIG. 5B as dimension D9), among other examples. One or more dimensions of the cavities 502, the quantity of cavities 502, and/or another parameter of the cavities 502 may be selected to reduce, minimize, and/or prevent optical crosstalk from resulting from reflections of incident light off of the metal grid structure 224. The one or more dimensions of the cavities 502, the quantity of cavities 502, and/or another parameter of the cavities 502 may be selected based on a size of the pixel sensors 100 (e.g., a width of the pixel sensors 100, based on a wavelength or wavelengths of incident light that is to be sensed by the pixel sensor array 222, spacing between adjacent pixel sensors 100, and/or another parameter).

In some implementations, the depth of a cavity 502 (dimension D6) is included in a range of approximately 1 nanometer to approximately 10 nanometers. However, other values for the range are within the scope of the present disclosure. In some implementations, the spacing between adjacent cavities 502 (dimension D7) is included in a range of approximately 1 nanometer to approximately 5 nanometers. However, other values for the range are within the scope of the present disclosure. In some implementations, the angle of the sidewalls of a cavity 502 (dimension D8) is included in a range of approximately 30 degrees to approximately 75 degrees. However, other values for the range are within the scope of the present disclosure. In some implementations, the width of a cavity 502 (dimension D9) is included in a range of approximately 1 nanometer to approximately 50 nanometers. However, other values for the range are within the scope of the present disclosure.

FIG. 5C illustrates an example 506 of a pixel sensor array 222, which is similar to the example 500 of the pixel sensor array 222 except that the cavities 502 having approximately curved, rounded, and/or semi-circular cross-sectional profiles are also included in the sidewalls 310 of the metal grid structure 224 in the example 504 of the pixel sensor array 222. Thus, the cavities 502 having approximately curved, rounded, and/or semi-circular cross-sectional profiles are included in the top surfaces 306 and the sidewalls 310 of the metal grid structure 224. The cavities 502 in the sidewalls 310 may provide further optical crosstalk reduction by scattering incident light directed to the sidewalls 310 of the metal grid structure 224.

FIG. 5D illustrates an example 508 of a pixel sensor array 222, which is similar to the example 504 of the pixel sensor array 222 except that the cavities 502 having approximately V-shaped (or triangular) cross-sectional profiles are also included in the sidewalls 310 of the metal grid structure 224 in the example 504 of the pixel sensor array 222. Thus, the cavities 502 having approximately V-shaped (or triangular) cross-sectional profiles are included in the top surfaces 306 and the sidewalls 310 of the metal grid structure 224. The cavities 502 in the sidewalls 310 may provide further optical crosstalk reduction by scattering incident light directed to the sidewalls 310 of the metal grid structure 224.

FIG. 5E illustrates an example 510 of a pixel sensor array 222, which is similar to the examples 506 and 508 of the pixel sensor arrays 222 except that the example 510 of the pixel sensor array 222 in FIG. 5E includes cavities 502 in the top surfaces 306 of the metal grid structure 224 and cavities 502 in the sidewalls 310 of the metal grid structure 224 that have different cross-sectional profiles. For example, the cavities 502 in the top surfaces 306 of the metal grid structure 224 may have approximately V-shaped (or triangular) cross-sectional profiles, and the cavities 502 in the sidewalls 310 of the metal grid structure 224 may have approximately curved, rounded, and/or semi-circular cross-sectional profiles (as illustrated in the example in FIG. 5E). As another example, the cavities 502 in the top surfaces 306 of the metal grid structure 224 may have approximately curved, rounded, and/or semi-circular cross-sectional profiles, and the cavities 502 in the sidewalls 310 of the metal grid structure 224 may have approximately V-shaped (or triangular) cross-sectional profiles. This enables greater flexibility in configuring the metal grid structure 224 for further optical crosstalk reduction for the pixel sensor array 222.

FIG. 5F illustrates an example 512 of a pixel sensor array 222, which is similar to the example 500 of the pixel sensor array 222 except that the metal grid structure 224 in the example 512 of the pixel sensor array 222 has a square-shaped cross-section shape or profile. Thus, the sidewalls 310 of the metal grid structure 224 are approximately perpendicular to the top surfaces 306 of the metal grid structure 224.

FIG. 5G illustrates an example 514 of a pixel sensor array 222, which is similar to the example 504 of the pixel sensor array 222 except that the metal grid structure 224 in the example 514 of the pixel sensor array 222 has a square-shaped cross-section shape or profile. Thus, the sidewalls 310 of the metal grid structure 224 are approximately perpendicular to the top surfaces 306 of the metal grid structure 224.

FIG. 5H illustrates an example 516 of a pixel sensor array 222, which is similar to the example 506 of the pixel sensor array 222 except that the metal grid structure 224 in the example 516 of the pixel sensor array 222 has a square-shaped cross-section shape or profile. Thus, the sidewalls 310 of the metal grid structure 224 are approximately perpendicular to the top surfaces 306 of the metal grid structure 224, and the cavities 502 in the sidewalls 310 of the metal grid structure 224 may have approximately curved, rounded, and/or semi-circular cross-sectional profiles.

FIG. 5I illustrates an example 518 of a pixel sensor array 222, which is similar to the example 508 of the pixel sensor array 222 except that the metal grid structure 224 in the example 518 of the pixel sensor array 222 has a square-shaped cross-section shape or profile. Thus, the sidewalls 310 of the metal grid structure 224 are approximately perpendicular to the top surfaces 306 of the metal grid structure 224, and the cavities 502 in the sidewalls 310 of the metal grid structure 224 may have approximately V-shaped (or triangular) cross-sectional profiles.

FIG. 5J illustrates an example 520 of a pixel sensor array 222, which is similar to the example 510 of the pixel sensor array 222 except that the metal grid structure 224 in the example 520 of the pixel sensor array 222 has a square-shaped cross-section shape or profile. Thus, the sidewalls 310 of the metal grid structure 224 are approximately perpendicular to the top surfaces 306 of the metal grid structure 224. The cavities 502 in the sidewalls 310 may have approximately V-shaped (or triangular) cross-sectional profiles, or may have approximately curved, rounded, and/or semi-circular cross-sectional profiles.

As indicated above, FIGS. 5A-5J is provided as examples. Other examples may differ from what is described with regard to FIGS. 5A-5J.

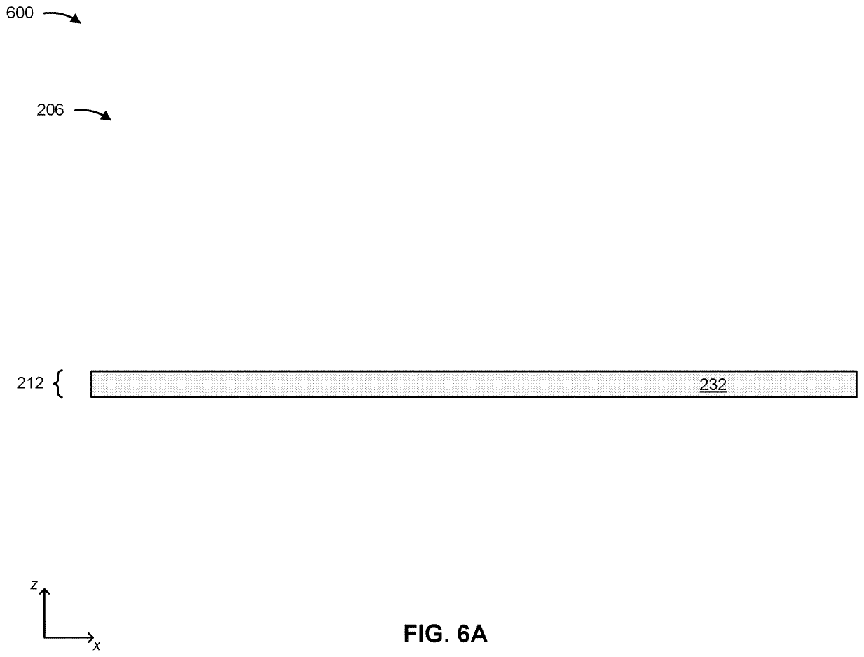

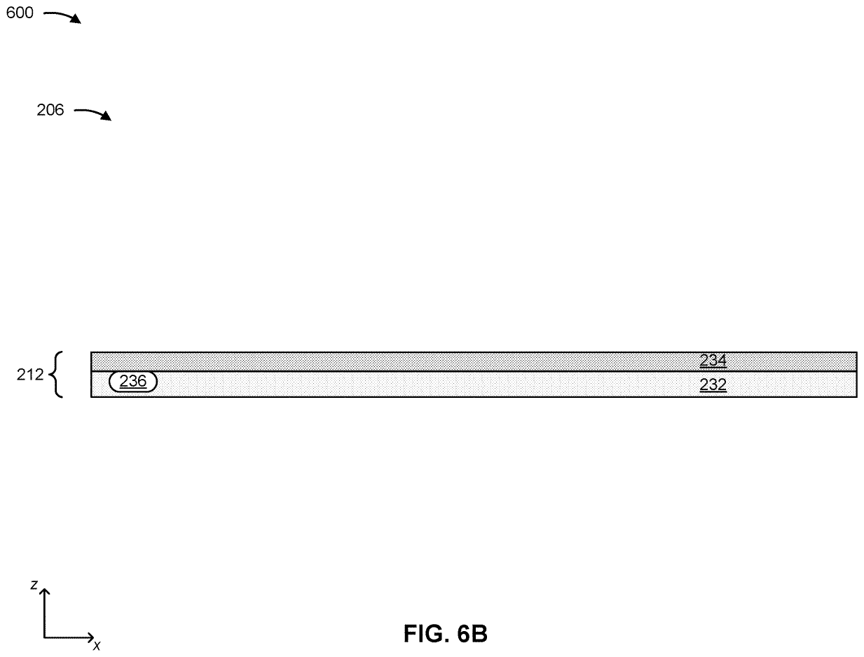

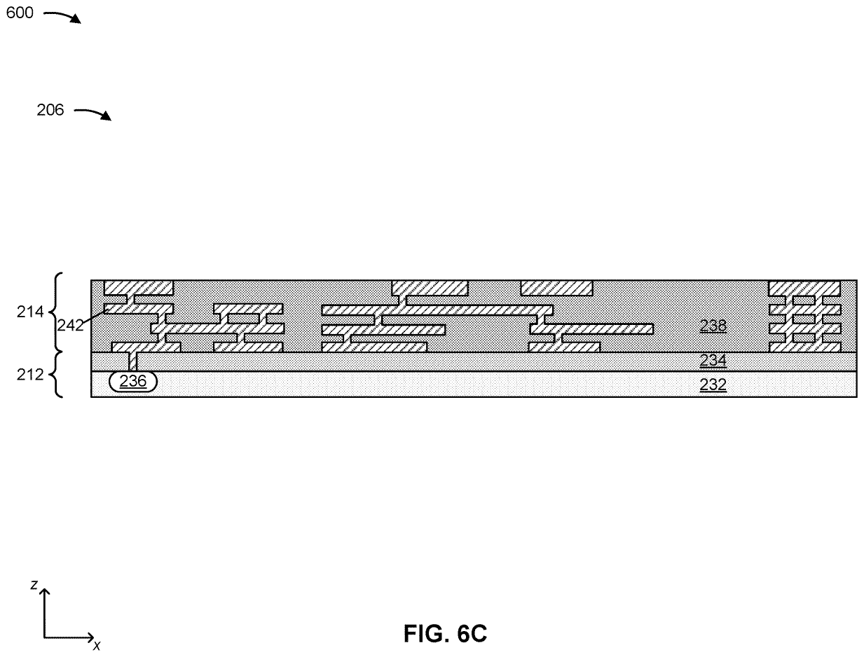

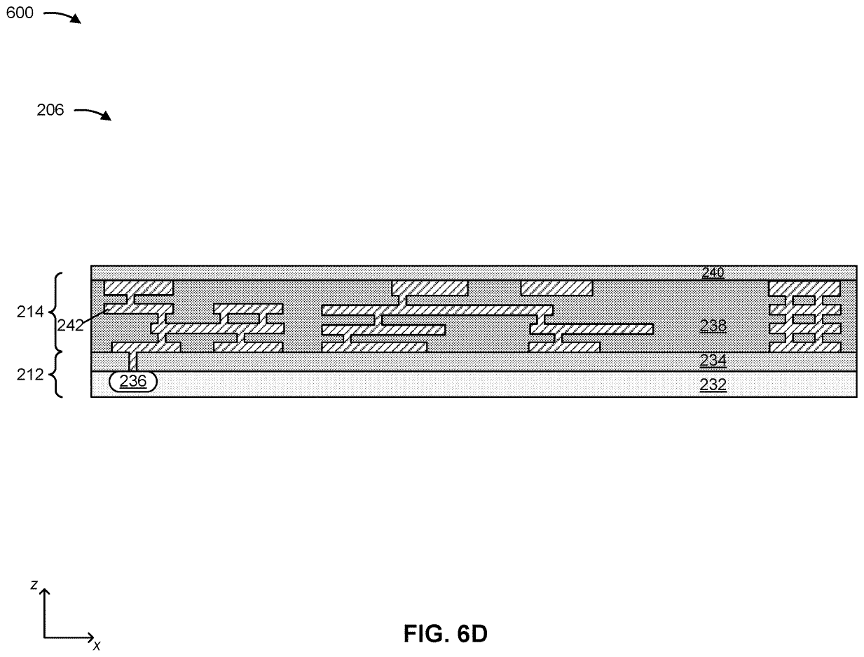

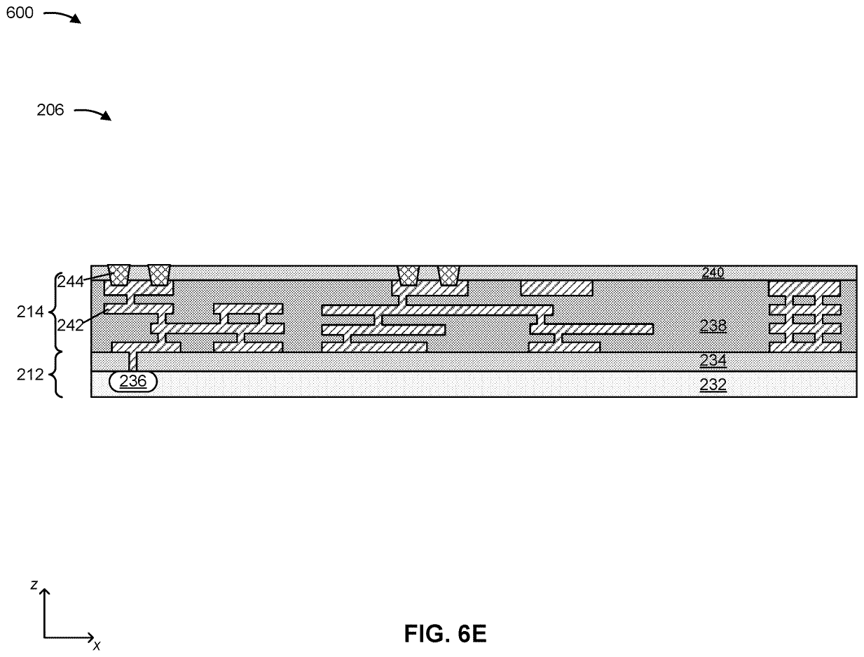

FIGS. 6A-6E are diagrams of an example implementation 600 of forming a circuitry die 206 (or a portion thereof) described herein. In some implementations, one or more of the semiconductor processing operations described in connection with FIGS. 6A-6E may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 6A, the substrate 232 of the device layer 212 of the circuitry die 206 is provided. The substrate 232 may be provided in the form of a semiconductor wafer such as a silicon (Si) wafer may be provided as an SOI wafer, and/or another type of semiconductor work piece.

As shown in FIG. 6B, one or more devices 236 may be formed in and/or on the substrate 232. One or more semiconductor processing tools may be used to form one or more portions of the devices 236. For example, a deposition tool may be used to perform various deposition operations to deposit layers of the devices 236, and/or to deposit photoresist layers for etching the substrate 232 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 232 and/or portions of the deposited layers to form the devices 236. As another example, a planarization tool may be used to planarize portions of the devices 236. As another example, a plating tool may be used to deposit metal structures and/or layers of the devices 236.

As further shown in FIG. 6B, a dielectric layer 234 may be deposited over and/or on the substrate 232 and over and/or on the devices 236. A deposition tool may be used to deposit the dielectric layer 234 using a physical vapor deposition (PVD) technique, an atomic layer deposition (ALD) technique, a chemical vapor deposition (CVD) technique, an oxidation technique, another type of deposition technique. In some implementations, a planarization tool may be used to planarize the dielectric layer 234 after the dielectric layer 234 is deposited.

As shown in FIG. 6C, a first portion of an interconnect layer 214 of the circuitry die 206 is formed above the device layer 212. To form the first portion of the interconnect layer 214, a deposition tool may be used to deposit a dielectric layer 238 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 238 after the dielectric layer 238 is deposited.

A deposition tool, an exposure tool, a developer tool, an etch tool, a planarization tool, a plating tool, and/or another semiconductor processing tool may be used to perform various operations to form interconnect structures 242 in the first portion of the interconnect layer 214. A deposition tool and/or a plating tool may be used to deposit the interconnect structures 242 using a PVD technique, an ALD technique, a CVD technique, an electroplating technique, and/or another deposition technique. In some implementations, a planarization tool may be used to planarize the interconnect structures 242 after the interconnect structures 242 are deposited.

In some implementations, first portion of the interconnect layer 214 is built up in the z-direction in a plurality of via layers (V-layers) and metallization layers (M-layers). For example, a first portion of the dielectric layer 238 may be formed, recesses may be formed in the first portion of the dielectric layer 238, and first interconnect structures 242 (e.g., a V0 via layer, an M0 metallization layer) may be formed in the recesses. A second portion of the dielectric layer 238 may be formed, recesses may be formed in the second portion of the dielectric layer 238, and second interconnect structures 242 (e.g., a V1 via layer, an M1 metallization layer) may be formed in the recesses. The remaining via layers and/or metallization layers of the first portion of the interconnect layer 214 may be formed in a similar manner.

As shown in FIGS. 6D and 6E, a second portion of the interconnect layer 214 may be formed, and the second portion of the interconnect layer 214 may include a bonding layer 240 and bonding structures 244. As shown in FIG. 6D, the bonding layer 240 may be formed over and/or on the dielectric layer 238, and over and/or on the top-most interconnect structures 242. A deposition tool may be used to deposit the bonding layer 240 using a PVD technique, an ALD technique, a CVD technique, an oxidation technique, another deposition technique. In some implementations, a planarization tool may be used to planarize the bonding layer 240 after the bonding layer 240 is deposited.

As shown in FIG. 6E, the bonding structures 244 may be formed in the bonding layer 240. For example, a deposition tool, an exposure tool, and a developer tool may be used to form a patterned masking layer on the bonding layer 240. An etch tool may be used to etch the bonding layer 240 (e.g., using a wet etch technique, a dry etch technique) to form recesses in the bonding layer 240. A deposition tool and/or a plating tool may be used to deposit the bonding structures 244 in the recess using a CVD technique, a PVD technique, an ALD technique, an electroplating technique, and/or another deposition technique. In some implementations, a planarization tool may perform a planarization operation to planarize the bonding structures 244 after the bonding structures 244 are deposited.

As indicated above, FIGS. 6A-6E are provided as an example. Other examples may differ from what is described with regard to FIGS. 6A-6E.

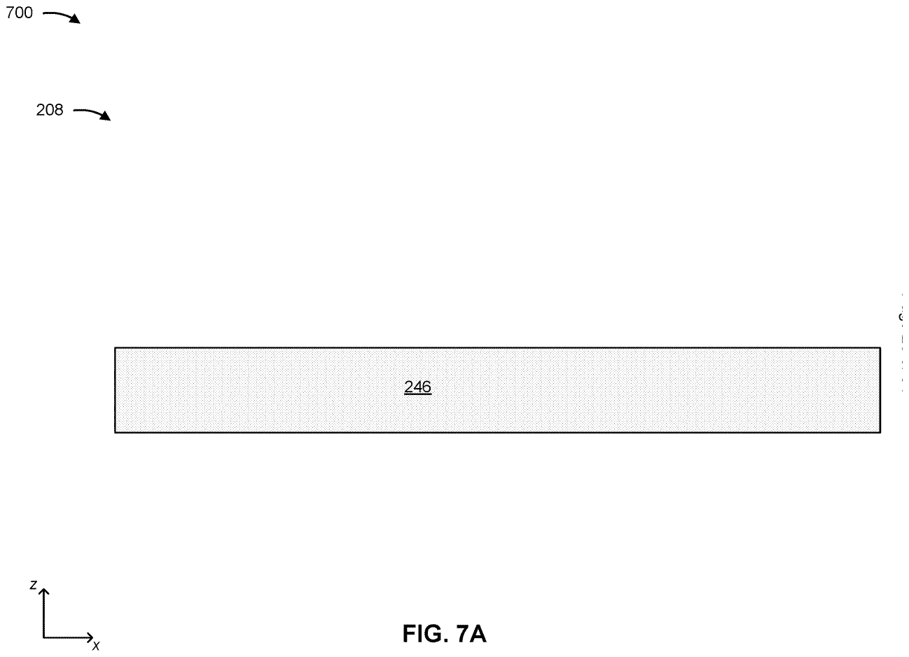

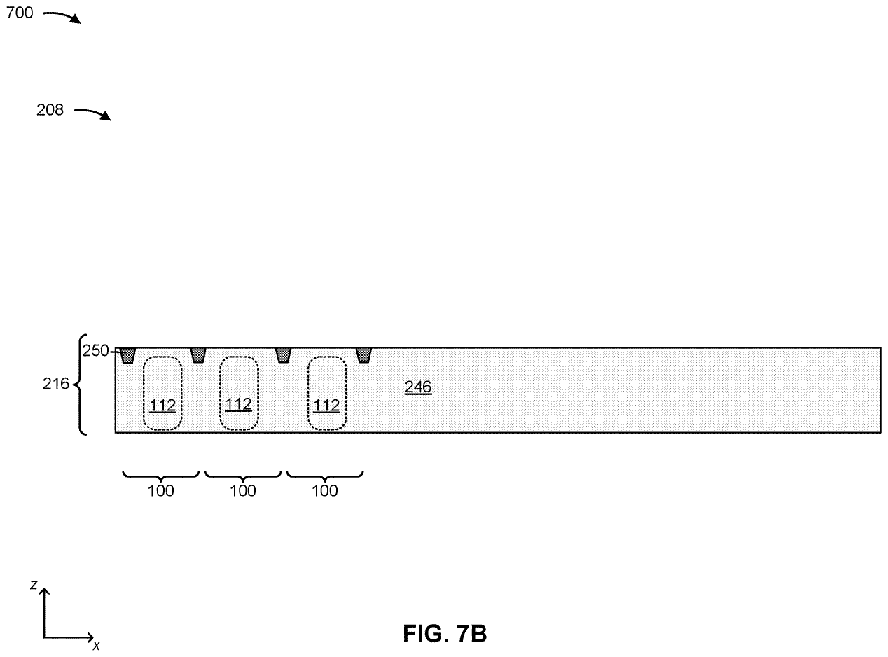

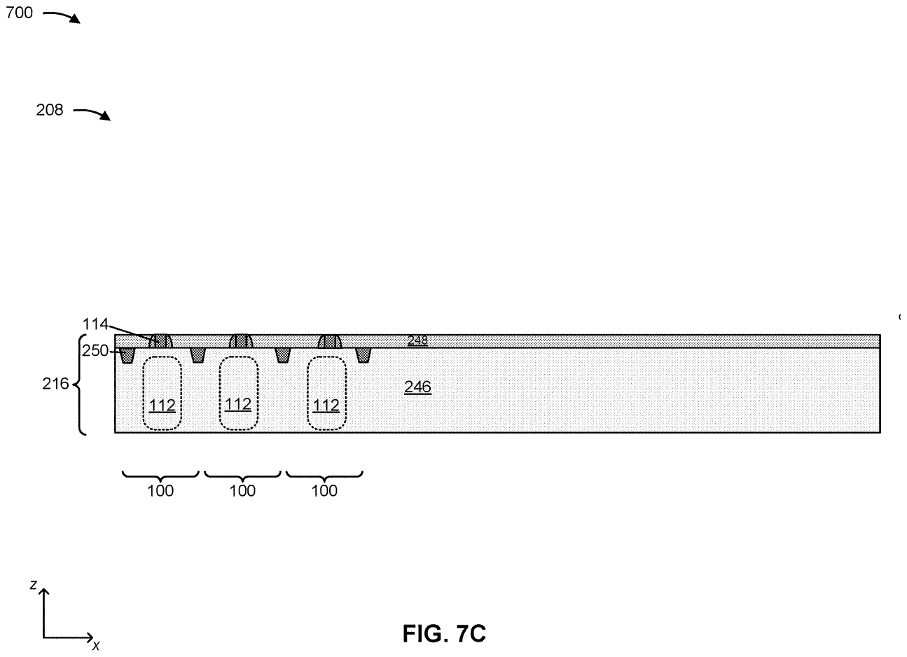

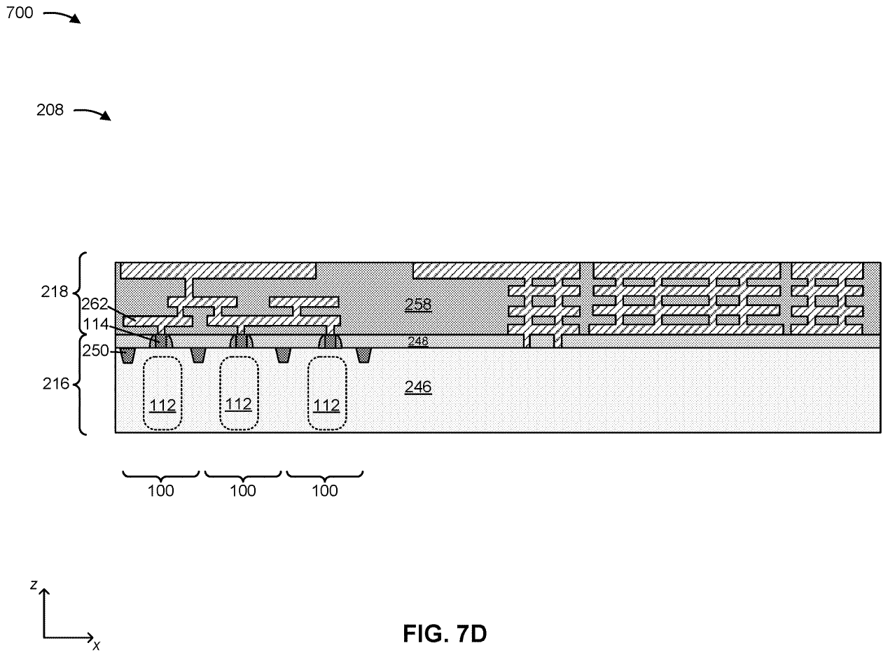

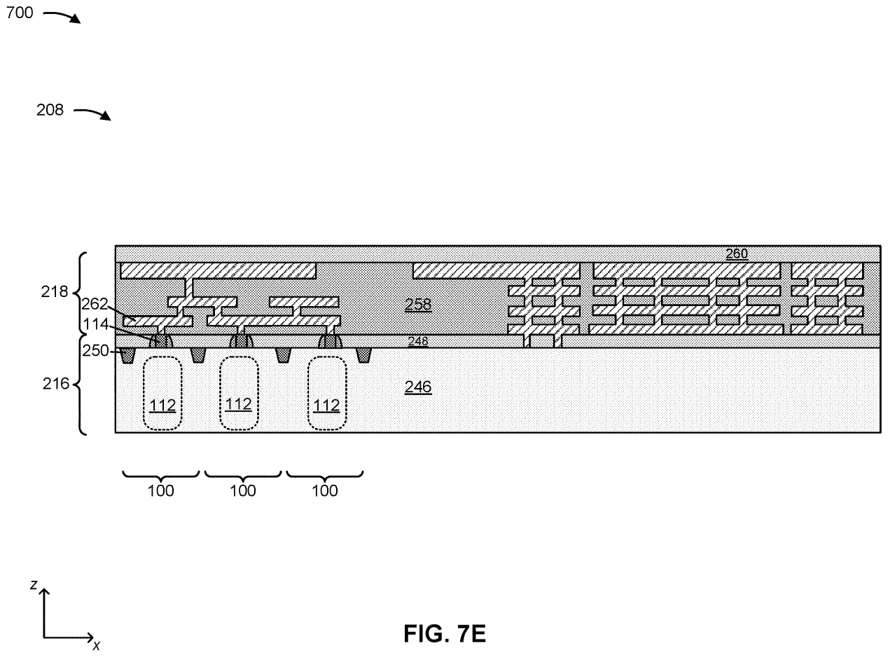

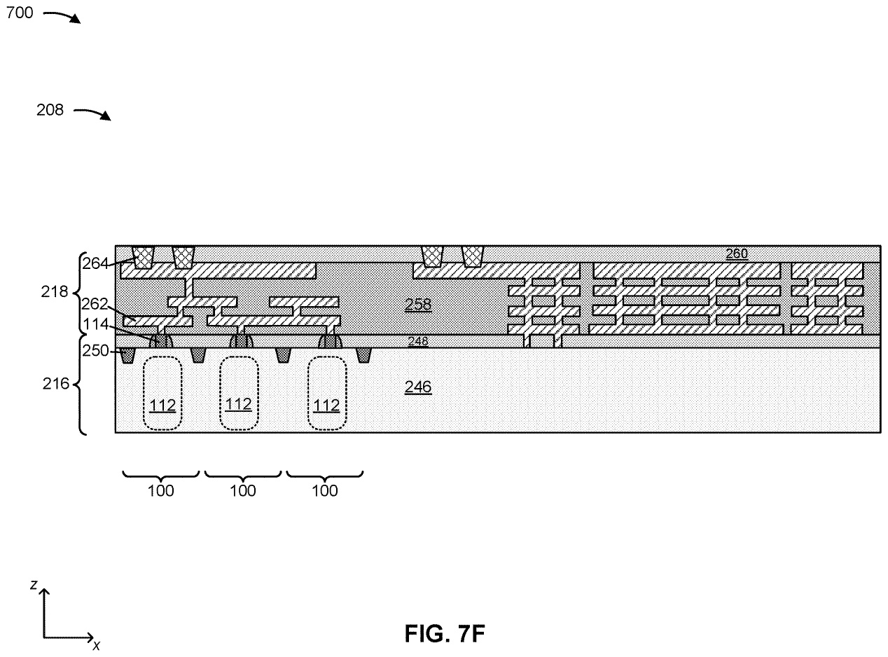

FIGS. 7A-7F are diagrams of an example implementation 700 of forming a sensor die 208 (or a portion thereof) described herein. In some implementations, one or more of the semiconductor processing operations described in connection with FIGS. 7A-7F may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 7A, the substrate 246 of the device layer 216 of the sensor die 208 is provided. The substrate 246 may be provided in the form of a semiconductor wafer such as a silicon (Si) wafer may be provided as an SOI wafer, and/or another type of semiconductor work piece.

As shown in FIG. 7B, photodiodes 112 of pixel sensors 100 of a pixel sensor array 222 of the sensor die 208 may be formed in the substrate 246 in the device layer 216 of the sensor die 208. In some implementations, an ion implantation tool may be used to implant ions into the substrate 246 to form a P-N junction between a p-doped region of the substrate 246 and an n-doped region of the substrate 246, or to form a P-I-N junction between p-doped region of the substrate 246, an n-doped region of the substrate 246, and an intrinsic (e.g., undoped) semiconductor region for a photodiode 112.

As further shown in FIG. 7B, STI structures 250 may be formed in the substrate 246 (e.g., from the front side of the substrate 246) such that the STI structures 250 are located between the photodiodes 112. In some implementations, the STI structures 250 are formed after the photodiodes 112 are formed. In some implementations, the STI structures 250 are formed prior to formation of the photodiodes 112. A deposition tool, an exposure tool, and a developer tool may be used to form a patterned masking layer on the substrate 246. An etch tool may be used to etch into the substrate 246 from the front side of the substrate 246 (e.g., using a wet etch technique, a dry etch technique) to form the recesses in the front side of the substrate 246. A deposition tool may be used to deposit the STI structures 250 in the recesses using a CVD technique, a PVD technique, an ALD technique, an oxidation technique, and/or another deposition technique. In some implementations, a planarization tool may perform a planarization operation to planarize the STI structures 250 after the STI structures 250 are deposited.

As shown in FIG. 7C, transfer gates 114 of the pixel sensors 100 may be formed over and/or on the front side surface of the substrate 246. Forming a transfer gate 114 may include deposing a gate dielectric on the front side surface of the substrate 246, depositing a gate electrode on the gate dielectric layer, and/or forming sidewall spacers on sidewalls of the gate electrode, among other examples.

As further shown in FIG. 7C, a dielectric layer 248 may be formed over and/or on the front side of the substrate 246, and over and/or on the transfer gates 114. A deposition tool may be used to deposit the dielectric layer 248 using a CVD technique, a PVD technique, an ALD technique, an electroplating technique, and/or another deposition technique. In some implementations, a planarization tool may perform a planarization operation to planarize the dielectric layer 248 after the dielectric layer 248 is deposited.

As shown in FIG. 7D, a first portion of an interconnect layer 218 of the sensor die 208 is formed above the device layer 216. To form the first portion of the interconnect layer 218, a deposition tool may be used to deposit a dielectric layer 258 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 258 after the dielectric layer 258 is deposited.

A deposition tool, an exposure tool, a developer tool, an etch tool, a planarization tool, a plating tool, and/or another semiconductor processing tool may be used to perform various operations to form interconnect structures 262 in the first portion of the interconnect layer 218. A deposition tool and/or a plating tool may be used to deposit the interconnect structures 262 using a PVD technique, an ALD technique, a CVD technique, an electroplating technique, and/or another deposition technique. In some implementations, a planarization tool may be used to planarize the interconnect structures 262 after the interconnect structures 262 are deposited.

In some implementations, first portion of the interconnect layer 218 is built up in the z-direction in a plurality of via layers (V-layers) and metallization layers (M-layers). For example, a first portion of the dielectric layer 258 may be formed, recesses may be formed in the first portion of the dielectric layer 258, and first interconnect structures 262 (e.g., a V0 via layer, an M0 metallization layer) may be formed in the recesses. A second portion of the dielectric layer 258 may be formed, recesses may be formed in the second portion of the dielectric layer 258, and second interconnect structures 262 (e.g., a V1 via layer, an M1 metallization layer) may be formed in the recesses. The remaining via layers and/or metallization layers of the first portion of the interconnect layer 218 may be formed in a similar manner.

As shown in FIGS. 7E and 7F, a second portion of the interconnect layer 218 may be formed, and the second portion of the interconnect layer 218 may include a bonding layer 260 and bonding structures 264. As shown in FIG. 7E, the bonding layer 260 may be formed over and/or on the dielectric layer 260, and over and/or on the top-most interconnect structures 262. A deposition tool may be used to deposit the bonding layer 260 using a PVD technique, an ALD technique, a CVD technique, an oxidation technique, another deposition technique. In some implementations, a planarization tool may be used to planarize the bonding layer 260 after the bonding layer 260 is deposited.

As shown in FIG. 7F, the bonding structures 264 may be formed in the bonding layer 260. For example, a deposition tool, an exposure tool, and a developer tool may be used to form a patterned masking layer on the bonding layer 260. An etch tool may be used to etch the bonding layer 260 (e.g., using a wet etch technique, a dry etch technique) to form recesses in the bonding layer 260. A deposition tool and/or a plating tool may be used to deposit the bonding structures 264 in the recess using a CVD technique, a PVD technique, an ALD technique, an electroplating technique, and/or another deposition technique. In some implementations, a planarization tool may perform a planarization operation to planarize the bonding structures 264 after the bonding structures 264 are deposited.

As indicated above, FIGS. 7A-7F are provided as an example. Other examples may differ from what is described with regard to FIGS. 7A-7F.

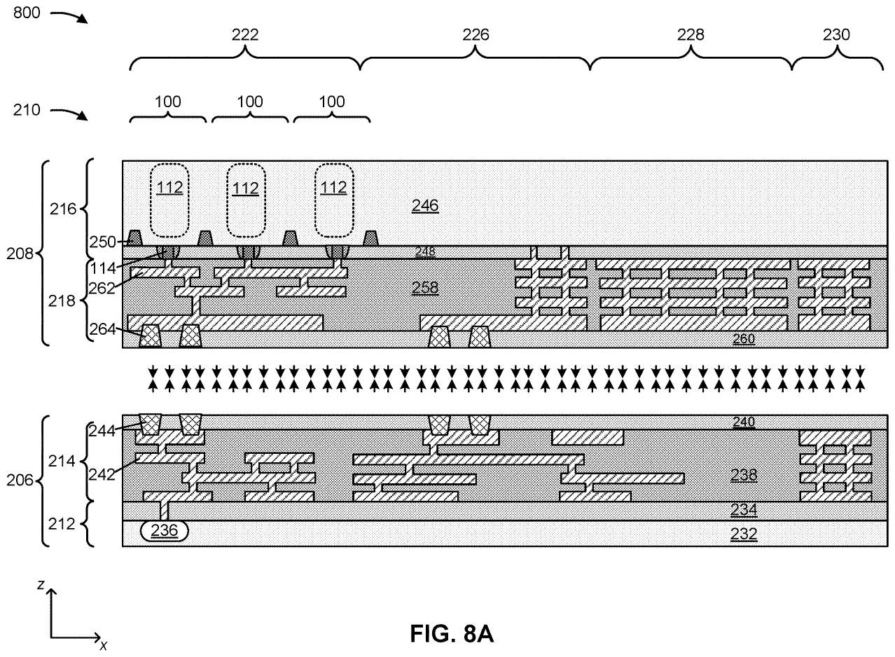

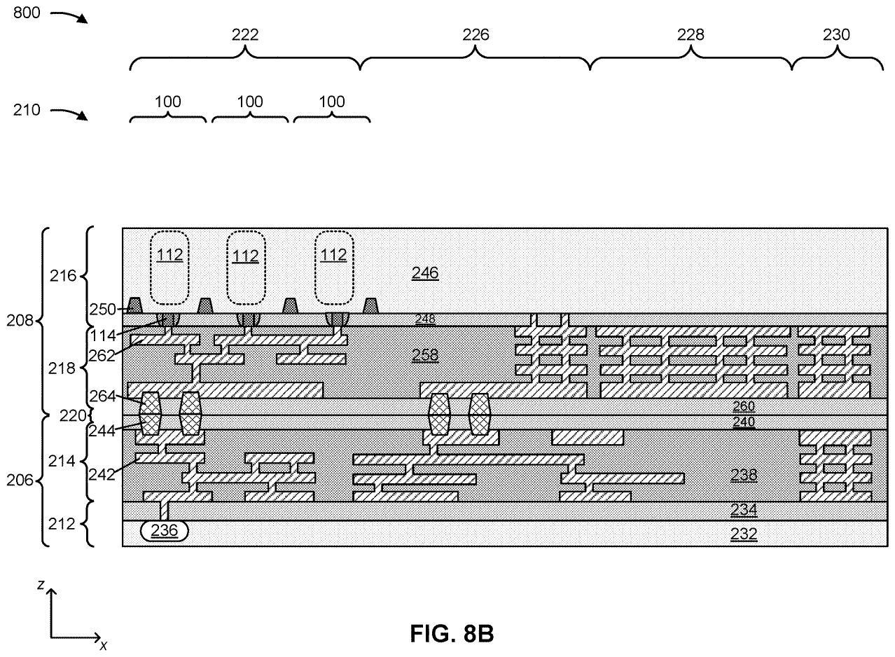

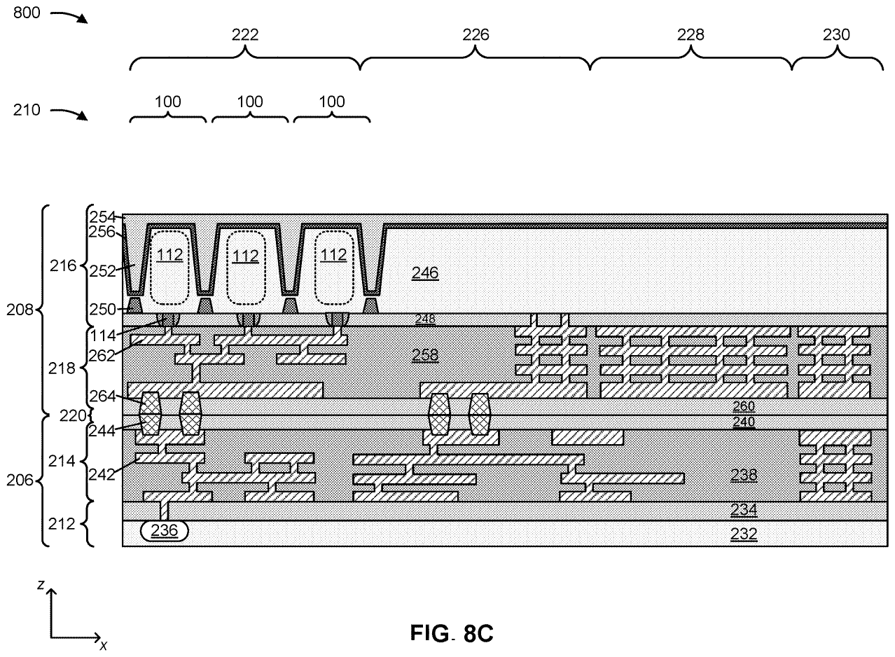

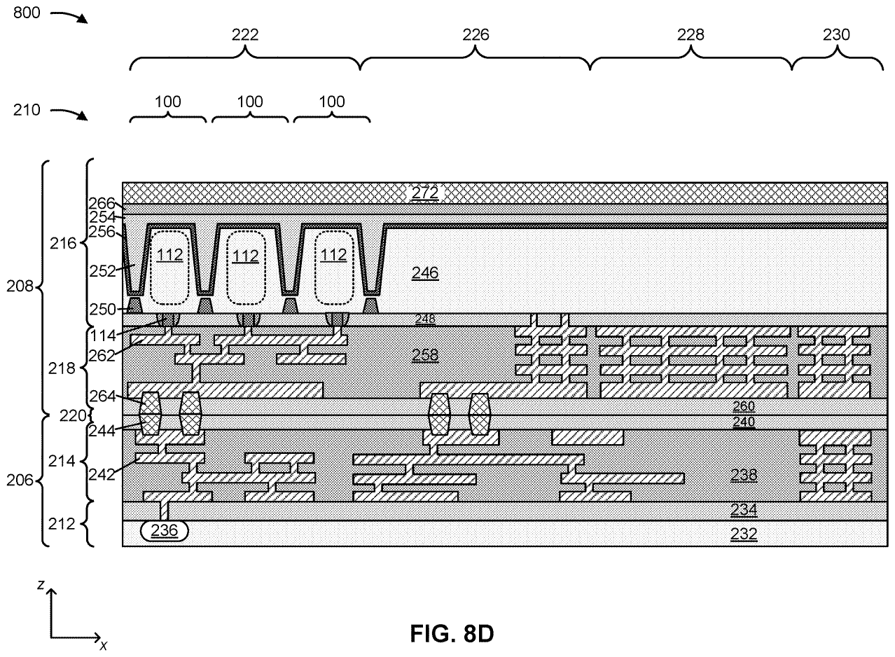

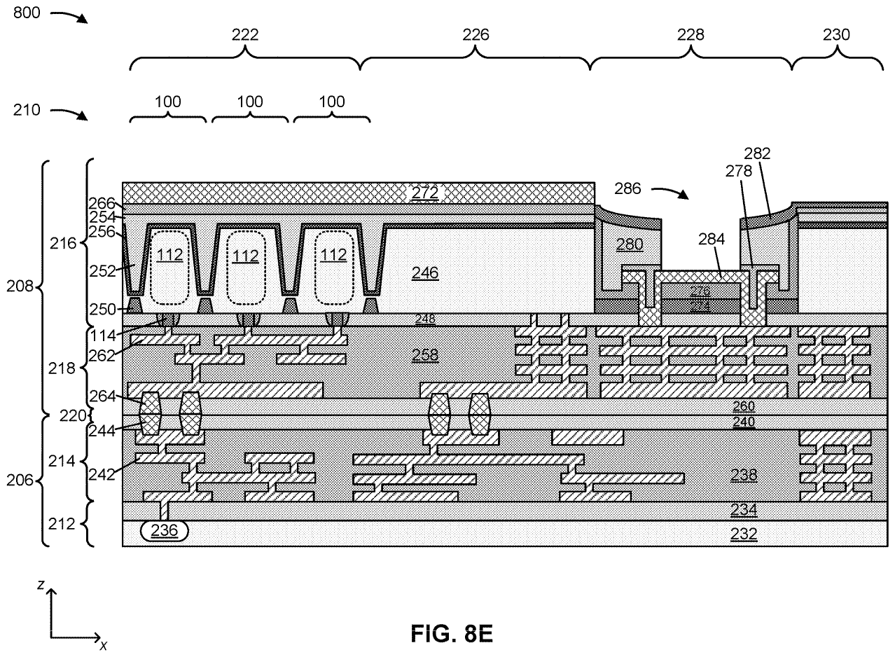

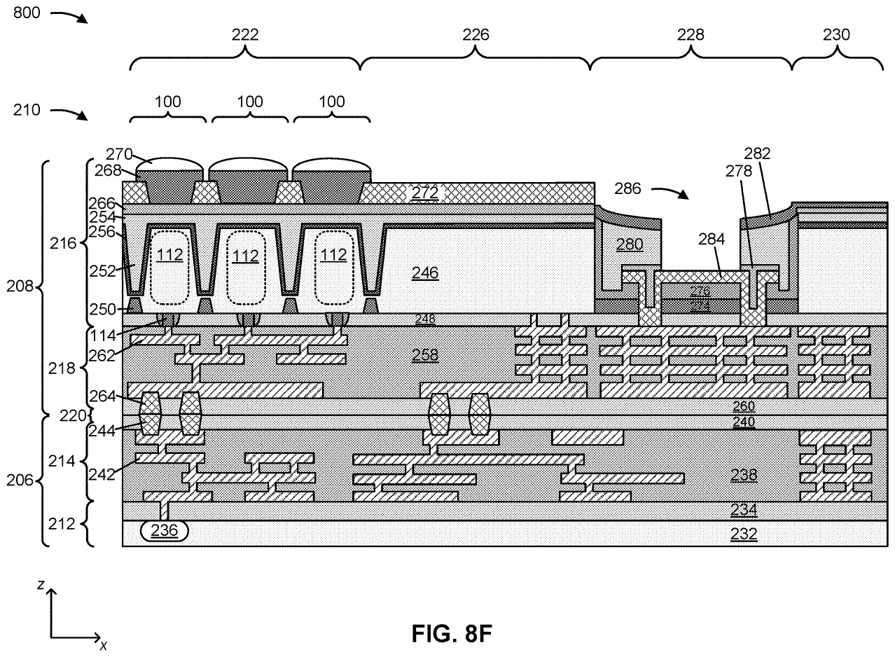

FIGS. 8A-8F are diagrams of an example implementation 800 of forming an image sensor device 210 (or a portion thereof) described herein. In some implementations, one or more of the semiconductor processing operations described in connection with FIGS. 8A-8F may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIGS. 8A and 8B, a bonding operation is performed to bond a circuitry die 206 and a sensor die 208 to form the image sensor device 210. The circuitry die 206 and the sensor die 208 may be bonded at a bonding interface 220, which may include the bonding layers 240 and 260 (respectively of the circuitry die 206 and the sensor die 208), and the bonding structures 244 and 264 (respectively of the circuitry die 206 and the sensor die 208). A bonding tool may be used to form a dielectric-to-dielectric bond between the bonding layers 240 and 260 at the bonding interface 220, and to form a metal-to-metal bond between the bonding structures 244 and 264 at the bonding interface 220.

As shown in FIG. 8B, after bonding, the circuitry die 206 and the sensor die 208 are stacked or vertically arranged in the z-direction in the image sensor device 210. The interconnect layer 214 of the circuitry die 206 and the interconnect layer 218 of the sensor die 208 are facing toward each other in the image sensor die 210, and the device layer 212 of the circuitry die 206 and the device layer 216 of the sensor die 208 are facing away from each other.

As shown in FIG. 8C, the DTI structure 252 may be formed in the substrate 246 (e.g., in the back side of the substrate 246) and around the photodiodes 112 in the substrate 246. For example, a deposition tool, an exposure tool, and a developer tool may be used to form a patterned masking layer on the substrate 246. An etch tool may be used to etch the substrate 246 (e.g., using a wet etch technique, a dry etch technique) from the back side of the substrate 246 to form trenches in the back side of the substrate 246. The trenches are above the STI structures 250 and alongside the photodiodes 112.

A deposition tool may be used to conformally deposit a dielectric liner 256 of the DTI structure 252 in the trenches and on the back side surface of the substrate 246 using a CVD technique, an ALD technique, and/or another conformal deposition technique. A deposition tool may be used to deposit the dielectric material 254 of the DTI structure 252 on the dielectric liner 256 in the trenches and above the substrate 246 using a CVD technique, a PVD technique, an ALD technique, an oxidation technique, and/or another deposition technique. In some implementations, a planarization tool may perform a planarization operation to planarize the dielectric material 254 above the substrate 246, which may remain as a buffer layer.

As shown in FIG. 8D, a passivation layer 266 may be formed over and/or on the buffer layer, and a metal layer 272 may be formed over and/or on the passivation layer over the back side of the substrate 246. A deposition tool and/or a plating tool may be used to deposit the passivation layer 266 using a CVD technique, a PVD technique, an ALD technique, an oxidation technique, and/or another deposition technique. In some implementations, a planarization tool may perform a planarization operation to planarize the passivation layer 266 after the passivation layer 266 is deposited. A deposition tool and/or a plating tool may be used to deposit the metal layer 272 using a CVD technique, a PVD technique, an ALD technique, an electroplating technique, and/or another deposition technique. In some implementations, a planarization tool may perform a planarization operation to planarize the metal layer 272 after the metal layer 272 is deposited.

As shown in FIG. 8E, various layers and/or structures may be formed in the bonding pad region 228 of the image sensor device 210. For example, a recess may be formed through the metal layer 272, through the passivation layer 266, through the buffer layer (corresponding to the dielectric material 254 above the substrate 246), through the dielectric liner 256, and/or through the substrate 246 to the dielectric layer 248. In some implementations, a deposition tool, an exposure tool, and a developer tool may be used to form a patterned masking layer on the metal layer 272. An etch tool may be used to etch the through the metal layer 272, through the passivation layer 266, through the buffer layer, through the dielectric liner 256, through the substrate 246 (e.g., using a wet etch technique, a dry etch technique) from the back side of the substrate 246 to form the recess.

A dielectric layer 274 may be formed in the recess on the dielectric layer 248. A dielectric layer 276 may be formed on the dielectric layer 274. A deposition tool may be used to deposit the dielectric layers 274 and 276 in the recess using a CVD technique, a PVD technique, an ALD technique, an oxidation technique, and/or another deposition technique.

Openings may be formed through the dielectric layers 248, 274, and 276 such that an interconnect structure 262 in the interconnect layer 218 is exposed through the recesses. A bonding pad structure 284 may be formed in the openings such that the bonding pad structure 284 lands on the interconnect structure 262. The bonding pad structure 284 is also formed on the dielectric layer 276.

In some implementations, a deposition tool, an exposure tool, and a developer tool may be used to form a patterned masking layer on the dielectric layer 276. An etch tool may be used to etch the through the dielectric layer 276, through the dielectric layer 274, and through the dielectric layer 248 (e.g., using a wet etch technique, a dry etch technique) to form the recesses. A deposition tool and/or a plating tool may be used to deposit the bonding pad structure 284 in the recess using a CVD technique, a PVD technique, an ALD technique, an electroplating technique, and/or another deposition technique.

A dielectric layer 278 may be formed on the bonding pad structure 284, and dielectric layers 280 and 282 may be deposited to fill in the recess in the bonding pad region 228. A bonding pad opening 286 may be formed through the dielectric layers 278, 280, and 282 to expose the bonding pad structure 284.

A deposition tool may be used to deposit the dielectric layers 278, 280, and 282 in the recess using a CVD technique, a PVD technique, an ALD technique, an oxidation technique, and/or another deposition technique. In some implementations, a deposition tool, an exposure tool, and a developer tool may be used to form a patterned masking layer on the dielectric layer 282. An etch tool may be used to etch the through the dielectric layers 278, 280, and 282 (e.g., using a wet etch technique, a dry etch technique) to form the bonding pad opening 286.

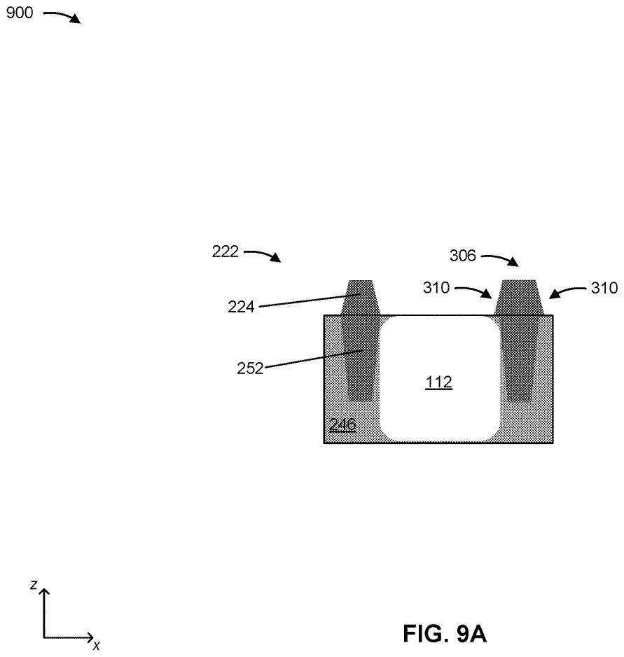

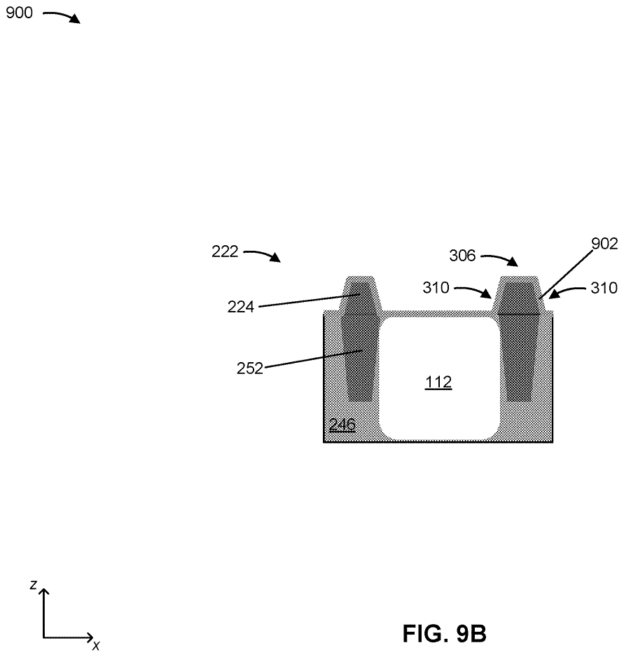

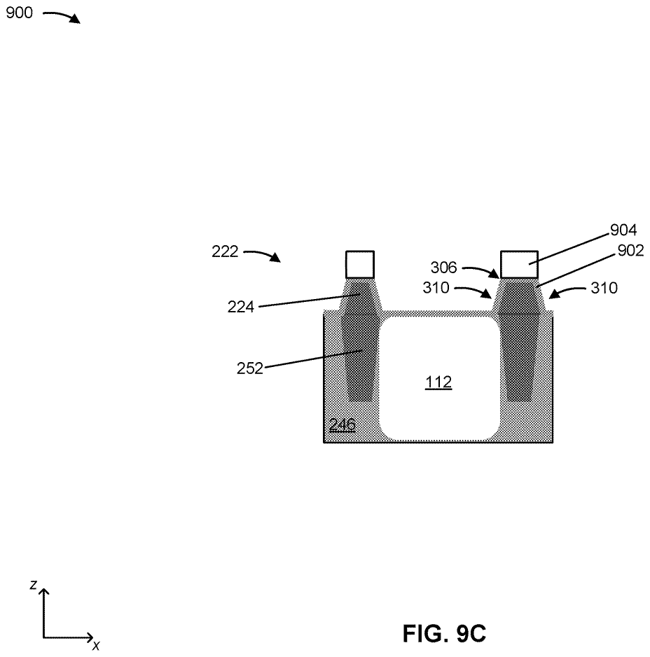

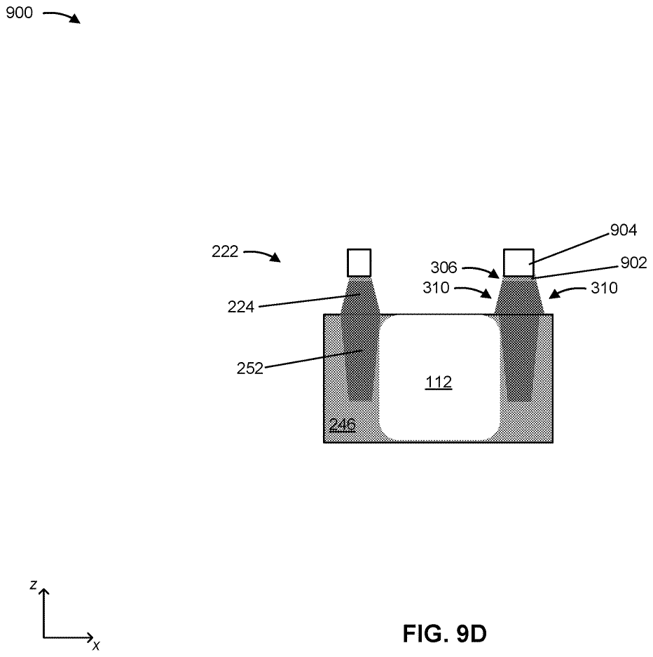

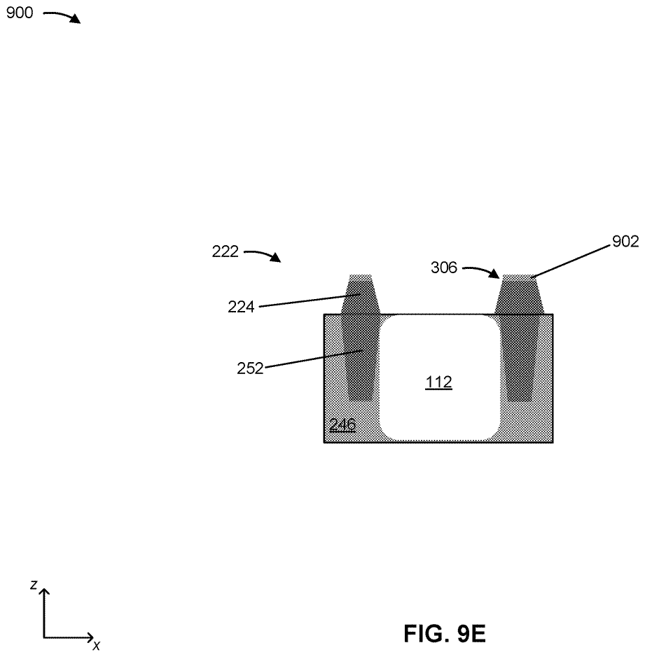

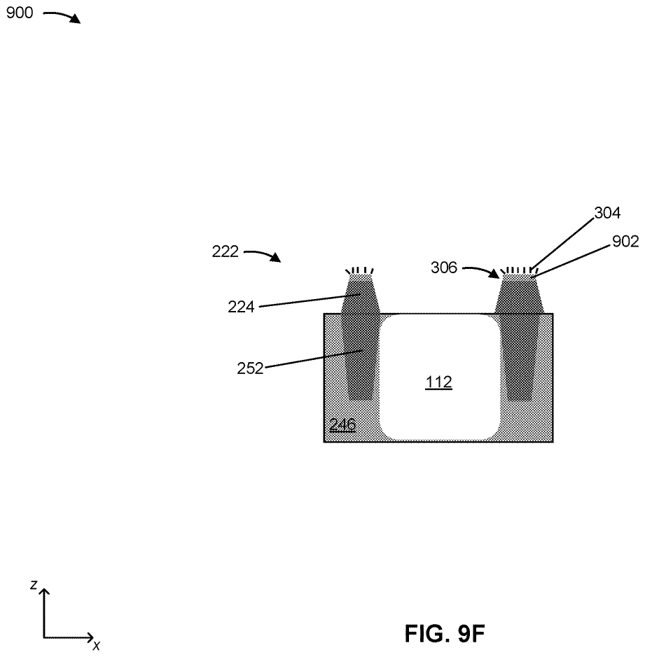

As shown in FIG. 8F, the metal layer 272 in the pixel sensor array 222 is etched to form the metal grid structure 224. Techniques described in connection with FIGS. 9A-9F, 10A-10D, 11A-11E, 12A-12C, 13A-13D, 14A, and/or 14B may be used to form antireflection structures in and/or on the metal grid structure 224.

In some implementations, a deposition tool, an exposure tool, and a developer tool may be used to form a patterned masking layer on the metal layer 272. An etch tool may be used to etch the through the metal layer 272 to the passivation layer 266 (e.g., using a wet etch technique, a dry etch technique) remove portions of the metal layer 272. Remaining portions of the metal layer 272 in the pixel sensor array 222 correspond to the metal grid structure 224 above the DTI structure 252.

As further shown in FIG. 8F, color filter regions 268 are formed in openings in the metal grid structure 224 such that the color filter regions 268 are located above and/or over the photodiodes 112 of the pixel sensors 100. Micro-lenses 270 are formed on the color filter regions 268.

As indicated above, FIGS. 8A-8F are provided as an example. Other examples may differ from what is described with regard to FIGS. 8A-8F.

FIGS. 9A-9F are diagrams of an example implementation 900 of forming nanostructures 304 on a metal grid structure 224 of a pixel sensor array 222 described herein. The techniques described in connection with FIGS. 9A-9F may be used to form nanostructures 304 in the examples of the pixel sensor arrays 222 illustrated and described in connection with FIGS. 3A and 3C (e.g., the examples in which the nanostructures 304 are included on the top surfaces 306 of the metal grid structures 224). In some implementations, one or more of the semiconductor processing operations described in connection with FIGS. 9A-9F may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 9A, the metal grid structure 224 may be formed above the backside surface of the substrate 246 such that the metal grid structure 224 is included above the DTI structure 252. An etch tool may be used to perform an etch operation to form the metal grid structure 224 from a metal layer (e.g., the metal layer 272). In some implementations, a dry etch technique such as a plasma-based etch technique is used to form the metal grid structure 224 such that the sidewalls 310 of the metal grid structure 224 are angled relative to a top surface 306 of the metal grid structure 224. This results in formation of an approximately trapezoidal cross-sectional profile for the metal grid structure 224. One or more parameters of the etch operation may be selected to etch the metal layer to form the approximately trapezoidal cross-sectional profile for the metal grid structure 224. The one or more parameters may include, for example, a bias voltage, a pressure, a temperature, and/or another parameter. Alternatively, the one or more parameters of the etch operation may be selected such that the dry etch results in formation of an approximately square cross-sectional profile for the metal grid structure 224. The one or more parameters selected for the etch operation may result in a more vertical etch to form the approximately square cross-sectional profile than for forming the approximately trapezoidal cross-sectional profile.

As shown in FIG. 9B, an antireflective layer 902 may be formed over and/or on the metal grid structure 224, as well as on the backside surface of the substrate 246. A deposition tool may be used to deposit the antireflective layer 902 using a CVD technique, a PVD technique, an ALD technique, an oxidation technique, and/or another deposition technique. In particular, a conformal deposition technique may be used to conformally deposit the antireflective layer 902 such that the antireflective layer 902 conforms to the profile of the metal grid structure 224. The antireflective layer 902 may include one or more antireflective materials, such as zinc oxide (ZnO), aluminum-doped zinc oxide (Al:ZnO or AZO), and/or aluminum oxide (AlₓO_{y} such as Al₃O₄), among other examples. The antireflective layer 902 may be formed as a substrate on which the nanostructures 304 are formed or grown.

As shown in FIG. 9C, a patterned masking layer 904 may be formed on the top surfaces 306 of the metal grid structure 224. A deposition tool may be used to form a masking layer on the backside of the substrate 246 and on the metal grid structure 224 (e.g., using a spin-coating technique and/or another deposition technique). An exposure tool may be used to expose the masking layer to form a pattern in the masking layer. A developer tool may be used to develop the pattern to form the patterned masking layer 904.

As shown in FIG. 9D, an etch tool may be used to etch the antireflective layer 902 to remove portions of the antireflective layer 902 from the backside of the substrate 246 and from the sidewalls 310 of the metal grid structure 224. Thus, the antireflective layer 902 remains only on the top surfaces 306 of the metal grid structure 224. The portions of the antireflective layer 902 may be removed using a wet etch technique, a dry etch technique, and/or another suitable etch technique.

As shown in FIG. 9E, the patterned masking layer 904 may be removed from the top surfaces 306 of the metal grid structure 224. The patterned masking layer 904 may be removed by etching the patterned masking layer 904, by ashing the patterned masking layer 904, and/or using another suitable masking layer removal technique.

As shown in FIG. 9F, the nanostructures 304 are formed on the antireflective layer 902 that is on the top surfaces 306 of the metal grid structure 224. A thermal anneal operation may be performed to form the nanostructures 304. For example, carbon (or graphite) powder may be deposited onto the antireflective layer 902 and annealed to cause the nanostructures 304 to grow from the carbon powder in a highly crystalline manner.

As indicated above, FIGS. 9A-9F are provided as an example. Other examples may differ from what is described with regard to FIGS. 9A-9F.

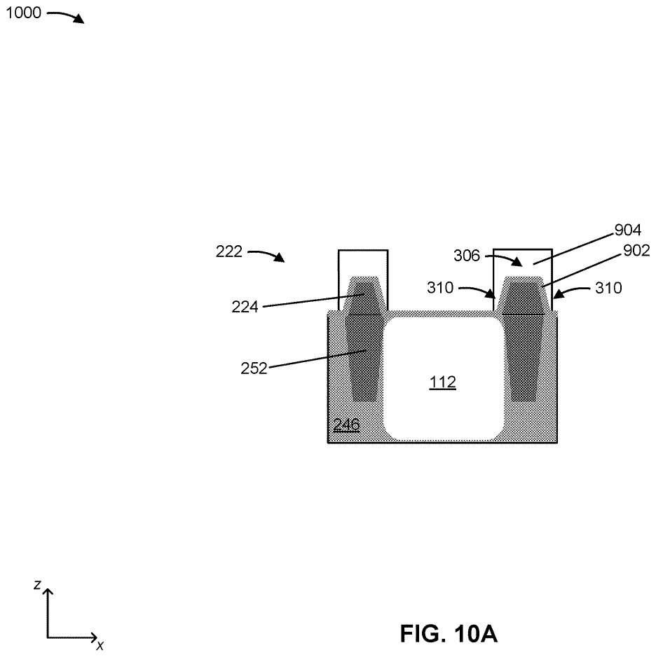

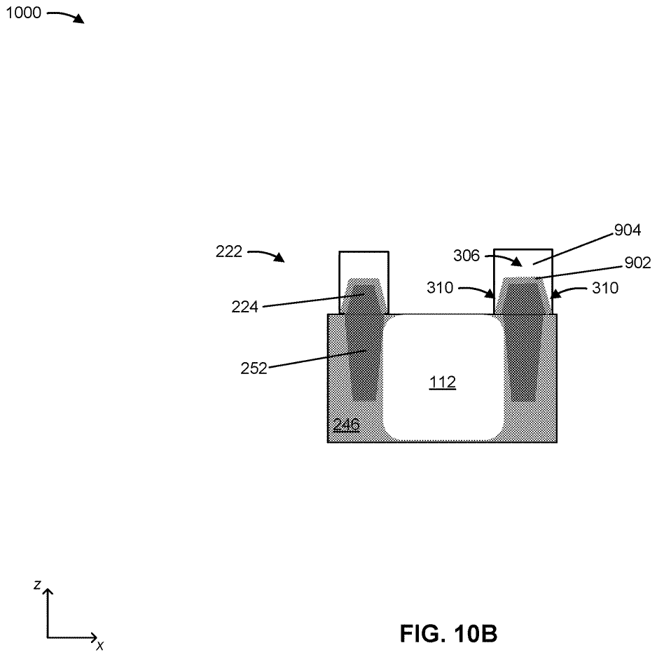

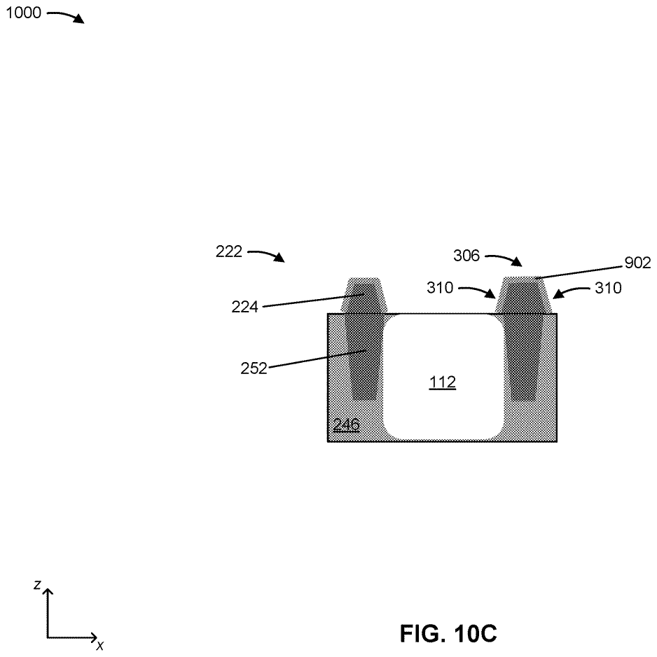

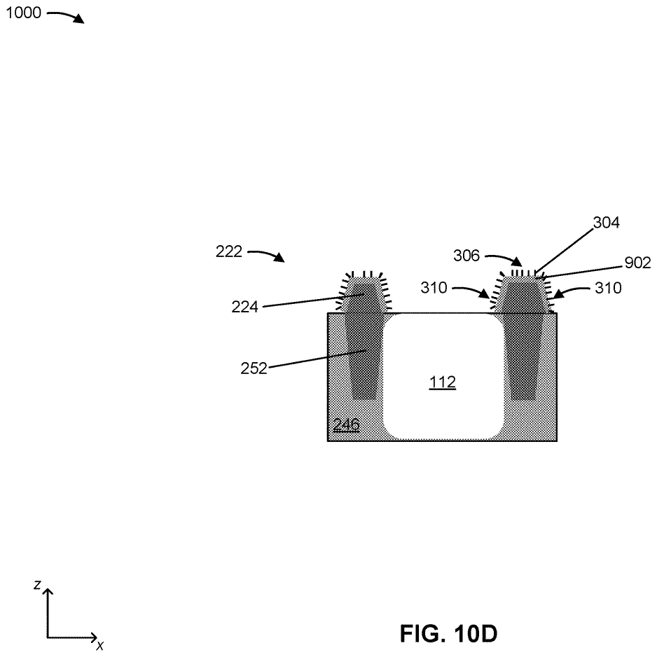

FIGS. 10A-10D are diagrams of an example implementation 1000 of forming nanostructures 304 on a metal grid structure 224 of a pixel sensor array 222 described herein. The techniques described in connection with FIGS. 10A-10D may be used to form nanostructures 304 in the examples of the pixel sensor arrays 222 illustrated and described in connection with FIGS. 3B and 3D (e.g., the examples in which the nanostructures 304 are included on the top surfaces 306 and sidewalls 310 of the metal grid structures 224). In some implementations, one or more of the semiconductor processing operations described in connection with FIGS. 10A-10D may be performed using one or more semiconductor processing tools, such as a deposition tool, an exposure tool, a developer tool, an etch tool, a planarization tool, a plating tool, an ion implantation tool, and/or a wafer/die transport tool, among other examples.

The example implementation 1000 is similar to the example implementation 900 of forming nanostructures 304 in that the metal grid structure 224 is formed, the antireflective layer 902 is formed on the top surfaces 306 and the sidewalls 310 of the metal grid structure 224 as well as on the backside of the substrate 246, and a patterned masking layer 904 is used to remove portions of the antireflective layer 902.

However, and as shown in FIG. 10A, the patterned masking layer 904 is also formed on the sidewalls 310 of the metal grid structure 224 in addition to the top surfaces 306 of the metal grid structure 224. As shown in FIG. 10B, this enables the portions of the antireflective layer 902 to be removed from the backside of the substrate 246 without removing the antireflective layer 902 from the top surfaces 306 and the sidewalls 310 of the metal grid structure 224. Thus, in the example implementation 1000 of forming nanostructures 304, the antireflective layer 902 is included on the top surfaces 306 and the sidewalls 310 of the metal grid structure 224. As shown in FIG. 10C, the patterned masking layer 904 is removed after the antireflective layer 902 is etched.

As shown in FIG. 10D, retaining the antireflective layer 902 on the sidewalls 310 of the metal grid structure 224 in the example implementation 1000 of forming nanostructures 304 enables the nanostructures 304 to be grown on the sidewalls 310 of the metal grid structure 224 in addition to the top surfaces 306 of the metal grid structure 224.

As indicated above, FIGS. 10A-10D are provided as an example. Other examples may differ from what is described with regard to FIGS. 10A-10D.

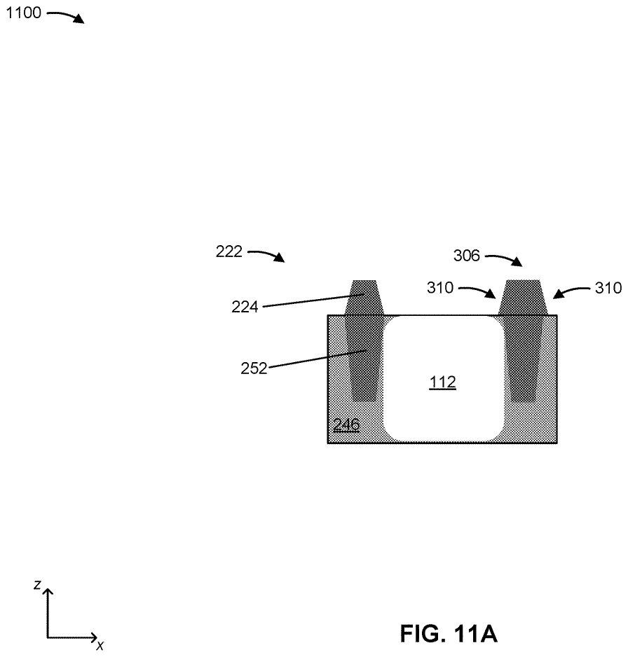

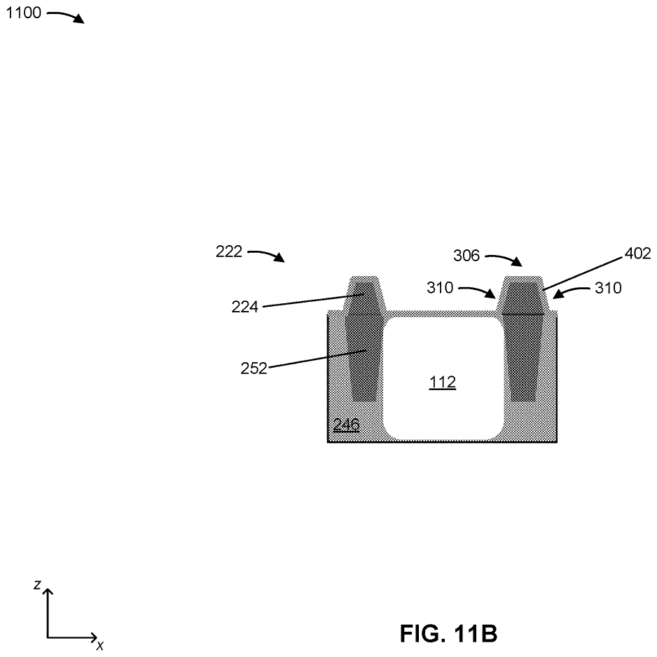

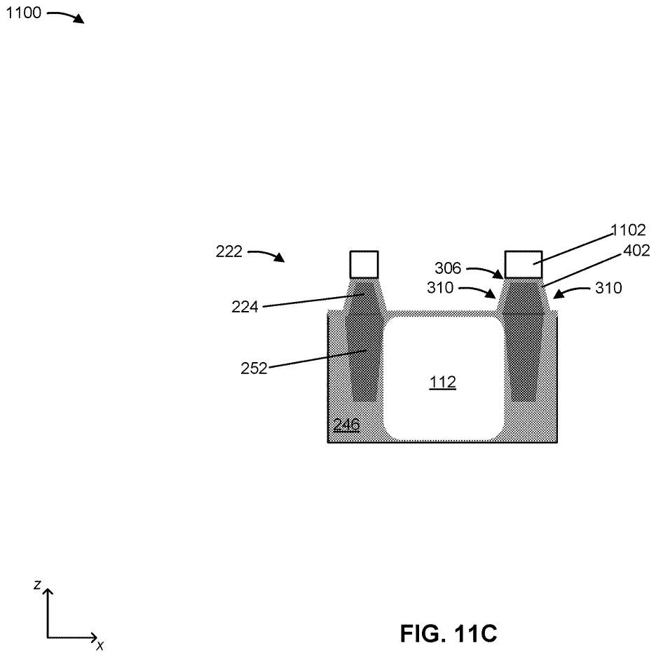

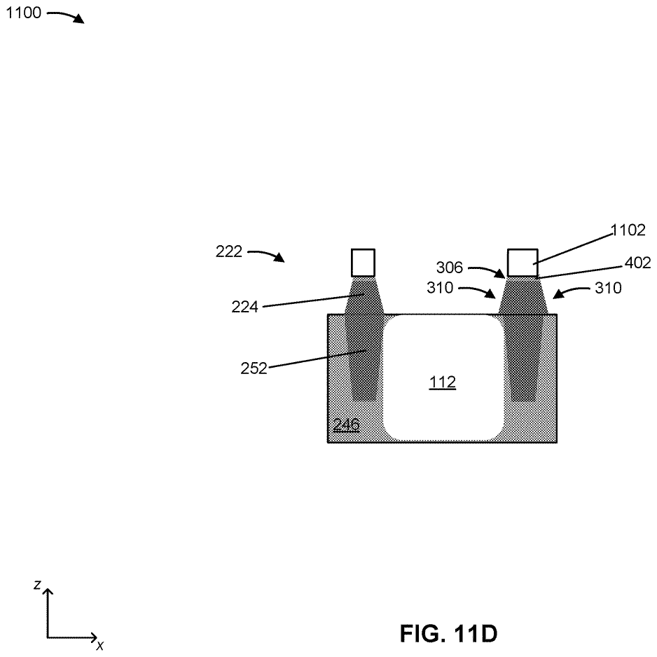

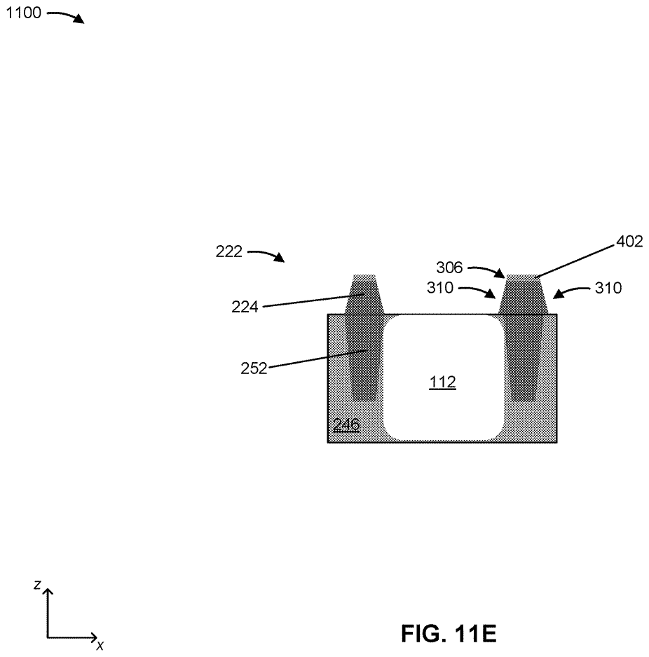

FIGS. 11A-11E are diagrams of an example implementation 1100 of forming antireflective layers 402 on a metal grid structure 224 of a pixel sensor array 222 described herein. The techniques described in connection with FIGS. 11A-11E may be used to form antireflective layers 402 in the examples of the pixel sensor arrays 222 illustrated and described in connection with FIGS. 4A and 4C (e.g., the examples in which the antireflective layers 402 are included on the top surfaces 306 of the metal grid structures 224). In some implementations, one or more of the semiconductor processing operations described in connection with FIGS. 11A-11E may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 11A, the metal grid structure 224 may be formed above the backside surface of the substrate 246 such that the metal grid structure 224 is included above the DTI structure 252. An etch tool may be used to perform an etch operation to form the metal grid structure 224 from a metal layer (e.g., the metal layer 272). In some implementations, a dry etch technique such as a plasma-based etch technique is used to form the metal grid structure 224 such that the sidewalls 310 of the metal grid structure 224 are angled relative to a top surface 306 of the metal grid structure 224. This results in formation of an approximately trapezoidal cross-sectional profile for the metal grid structure 224. One or more parameters of the etch operation may be selected to etch the metal layer to form the approximately trapezoidal cross-sectional profile for the metal grid structure 224. The one or more parameters may include, for example, a bias voltage, a pressure, a temperature, and/or another parameter. Alternatively, the one or more parameters of the etch operation may be selected such that the dry etch results in formation of an approximately square cross-sectional profile for the metal grid structure 224. The one or more parameters selected for the etch operation may result in a more vertical etch to form the approximately square cross-sectional profile than for forming the approximately trapezoidal cross-sectional profile.

As shown in FIG. 11B, the antireflective layer 402 may be formed over and/or on the metal grid structure 224, as well as on the backside surface of the substrate 246. A deposition tool may be used to deposit the antireflective layer 902 using a CVD technique, a PVD technique, an ALD technique, an oxidation technique, and/or another deposition technique. In particular, a conformal deposition technique may be used to conformally deposit the antireflective layer 402 such that the antireflective layer 402 conforms to the profile of the metal grid structure 224.

As shown in FIG. 11C, a patterned masking layer 1102 may be formed on the top surfaces 306 of the metal grid structure 224. A deposition tool may be used to form a masking layer on the backside of the substrate 246 and on the metal grid structure 224 (e.g., using a spin-coating technique and/or another deposition technique). An exposure tool may be used to expose the masking layer to form a pattern in the masking layer. A developer tool may be used to develop the pattern to form the patterned masking layer 1102.

As shown in FIG. 11D, an etch tool may be used to etch the antireflective layer 402 remove portions of the antireflective layer 402 from the backside of the substrate 246 and from the sidewalls 310 of the metal grid structure 224. Thus, the antireflective layer 402 remains only on the top surfaces 306 of the metal grid structure 224. The portions of the antireflective layer 402 may be removed using a wet etch technique, a dry etch technique, and/or another suitable etch technique.

As shown in FIG. 11E, the patterned masking layer 1102 may be removed from the top surfaces 306 of the metal grid structure 224. The patterned masking layer 1102 may be removed by etching the patterned masking layer 1102, by ashing the patterned masking layer 1102, and/or using another suitable masking layer removal technique.

As indicated above, FIGS. 11A-11E are provided as an example. Other examples may differ from what is described with regard to FIGS. 11A-11E.

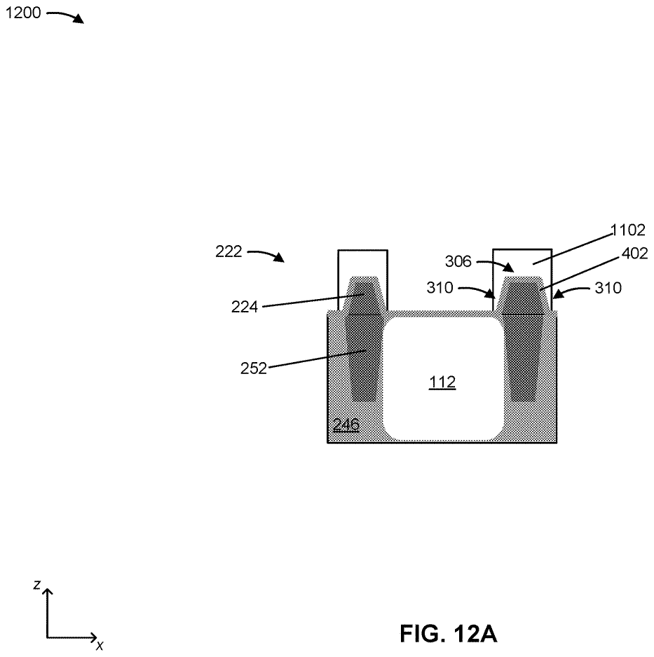

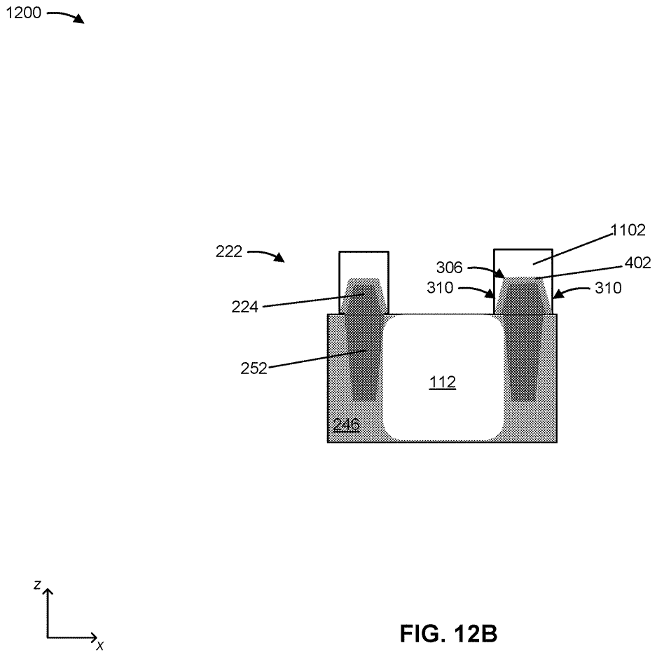

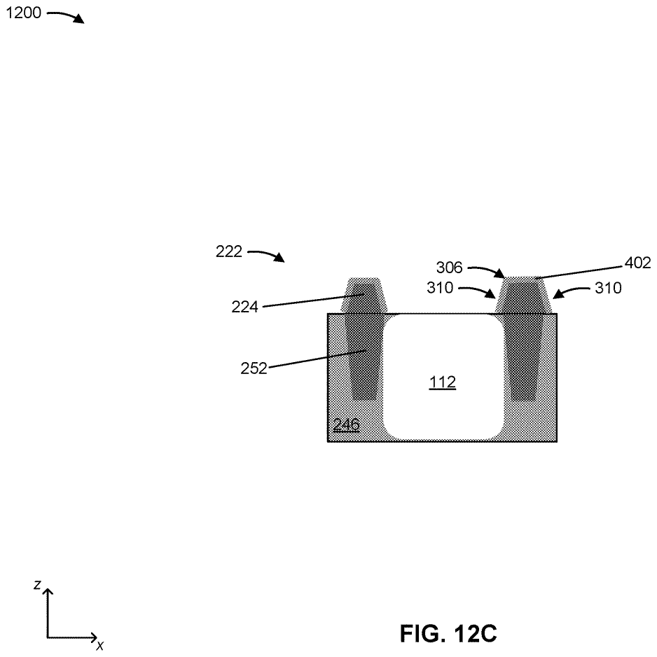

FIGS. 12A-12C are diagrams of an example implementation 1200 of forming antireflective layers 402 on a metal grid structure 224 of a pixel sensor array 222 described herein. The techniques described in connection with FIGS. 12A-12C may be used to form antireflective layers 402 in the examples of the pixel sensor arrays 222 illustrated and described in connection with FIGS. 4B and 4D (e.g., the examples in which the antireflective layers 402 are included on the top surfaces 306 and sidewalls 310 of the metal grid structures 224). In some implementations, one or more of the semiconductor processing operations described in connection with FIGS. 12A-12C may be performed using one or more semiconductor processing tools, such as a deposition tool, an exposure tool, a developer tool, an etch tool, a planarization tool, a plating tool, an ion implantation tool, and/or a wafer/die transport tool, among other examples.

The example implementation 1200 is similar to the example implementation 1100 of forming antireflective layers 402 in that the metal grid structure 224 is formed, the antireflective layers 402 is formed on the top surfaces 306 and the sidewalls 310 of the metal grid structure 224 as well as on the backside of the substrate 246, and a patterned masking layer 1102 is used to remove portions of the antireflective layer 902.

However, and as shown in FIG. 12A, the patterned masking layer 1102 is also formed on the sidewalls 310 of the metal grid structure 224 in addition to the top surfaces 306 of the metal grid structure 224. As shown in FIG. 12B, this enables the portions of the antireflective layer 402 to be removed from the backside of the substrate 246 without removing the antireflective layer 402 from the top surfaces 306 and the sidewalls 310 of the metal grid structure 224. Thus, in the example implementation 1200 of forming antireflective layers 402, the antireflective layers 402 are included on the top surfaces 306 and on the sidewalls 310 of the metal grid structure 224. As shown in FIG. 12C, the patterned masking layer 904 is removed after the antireflective layer 402 is etched.

As indicated above, FIGS. 12A-12C are provided as an example. Other examples may differ from what is described with regard to FIGS. 12A-12C.

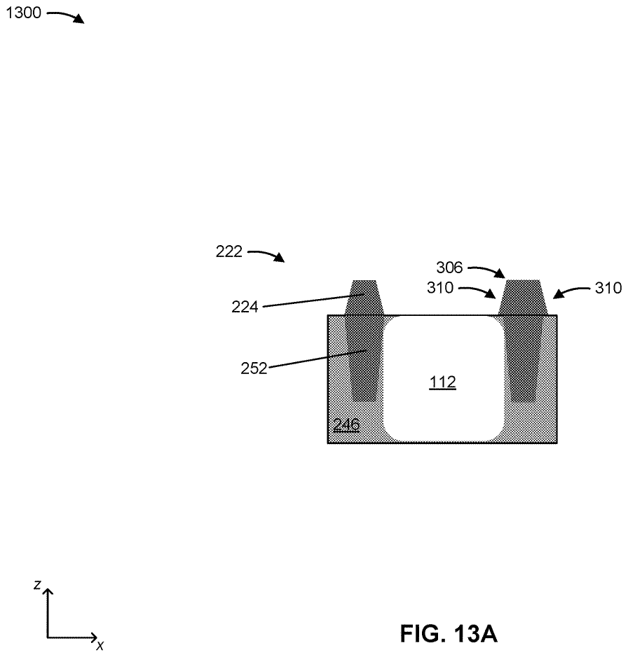

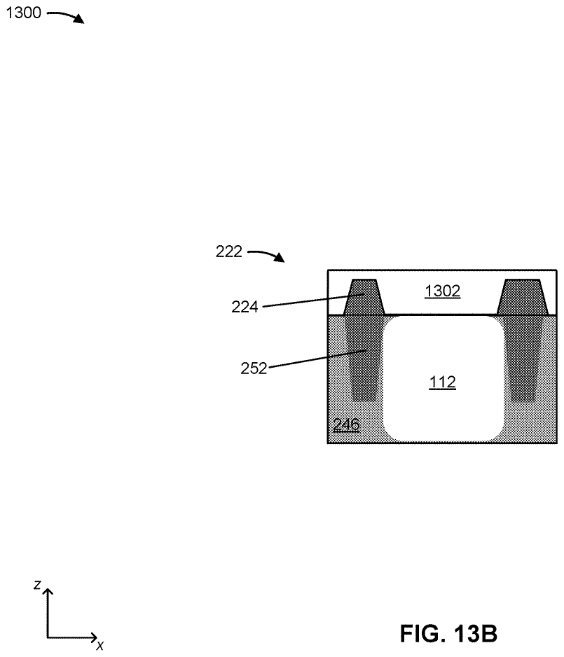

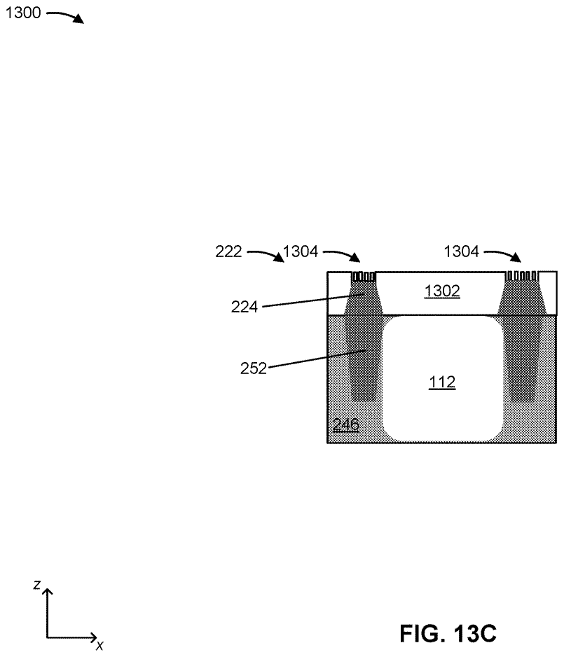

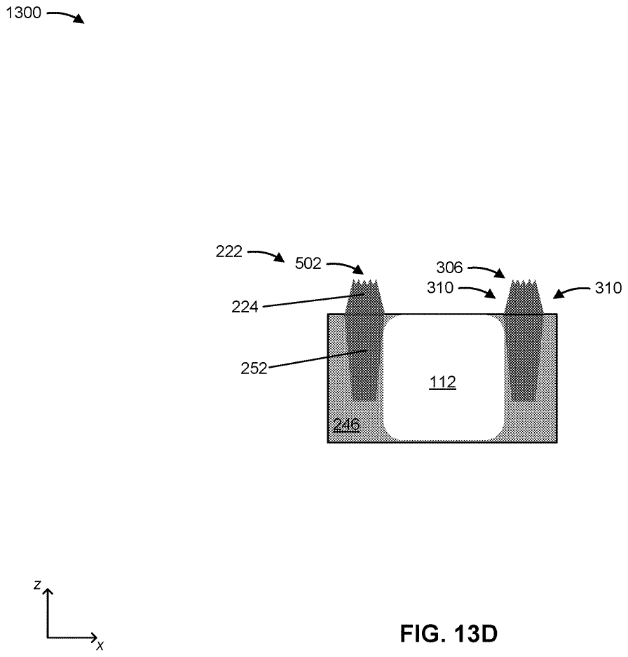

FIGS. 13A-13D are diagrams of an example implementation 1300 of forming cavities 502 in a metal grid structure 224 of a pixel sensor array 222 described herein. The techniques described in connection with FIGS. 13A-13D may be used to form cavities 502 in the examples of the pixel sensor arrays 222 illustrated and described in connection with FIGS. 5A, 5B, 5F, and 5G (e.g., the examples in which the cavities 502 are included in the top surfaces 306 of the metal grid structures 224). In some implementations, one or more of the semiconductor processing operations described in connection with FIGS. 13A-13D may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 13A, the metal grid structure 224 may be formed above the backside surface of the substrate 246 such that the metal grid structure 224 is included above the DTI structure 252. An etch tool may be used to perform an etch operation to form the metal grid structure 224 from a metal layer (e.g., the metal layer 272). In some implementations, a dry etch technique such as a plasma-based etch technique is used to form the metal grid structure 224 such that the sidewalls 310 of the metal grid structure 224 are angled relative to a top surface 306 of the metal grid structure 224. This results in formation of an approximately trapezoidal cross-sectional profile for the metal grid structure 224. One or more parameters of the etch operation may be selected to etch the metal layer to form the approximately trapezoidal cross-sectional profile for the metal grid structure 224. The one or more parameters may include, for example, a bias voltage, a pressure, a temperature, and/or another parameter. Alternatively, the one or more parameters of the etch operation may be selected such that the dry etch results in formation of an approximately square cross-sectional profile for the metal grid structure 224. The one or more parameters selected for the etch operation may result in a more vertical etch to form the approximately square cross-sectional profile than for forming the approximately trapezoidal cross-sectional profile.

As shown in FIGS. 13B and 13C, a masking layer 1302 may be formed on the metal grid structure 224 and on the backside of the substrate 246, and a pattern 1304 may be formed in the masking layer 1302. A deposition tool may be used to form a masking layer 1302 on the backside of the substrate 246 and on the metal grid structure 224 (e.g., using a spin-coating technique and/or another deposition technique). An exposure tool may be used to expose the masking layer 1302 to form the pattern 1304 in the masking layer. A developer tool may be used to develop the pattern 1304. The pattern 1304 may include openings in the masking layer 1302 above the top surfaces 306 of the metal grid structure 224.

An etch tool may be used to etch the top surfaces 306 of the metal grid structure 224 based on the pattern 1304 in the masking layer 1302 to form the cavities 502 in the top surfaces 306 of the metal grid structure 224, as shown in FIG. 13D.

In some implementations, the cavities 502 may be formed using a wet etch technique, in which a wet etchant is provided to the top surfaces 306 of the metal grid structure 224 through the pattern 1304 in the masking layer 1302, and the wet etchant removes material from the top surfaces 306 of the metal grid structure 224. This results in formation of the cavities in the top surfaces 306 of the metal grid structure 224. In some implementations, using a wet etch technique results in the cavities 502 having approximately curved, rounded, and/or semi-circular cross-sectional profiles.

In some implementations, the cavities 502 may be formed using a dry etch technique, in which a plasma and/or another type of dry etchant is provided to the top surfaces 306 of the metal grid structure 224 through the pattern 1304 in the masking layer 1302, and the dry etchant removes material from the top surfaces 306 of the metal grid structure 224. This results in formation of the cavities in the top surfaces 306 of the metal grid structure 224. In some implementations, using a dry etch technique results in the cavities 502 having approximately V-shaped (or triangular) cross-sectional profiles.

As indicated above, FIGS. 13A-13D are provided as an example. Other examples may differ from what is described with regard to FIGS. 13A-13D.

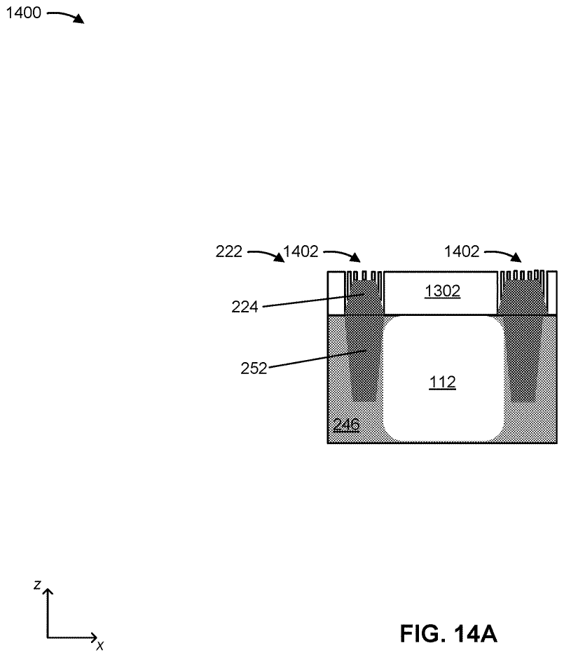

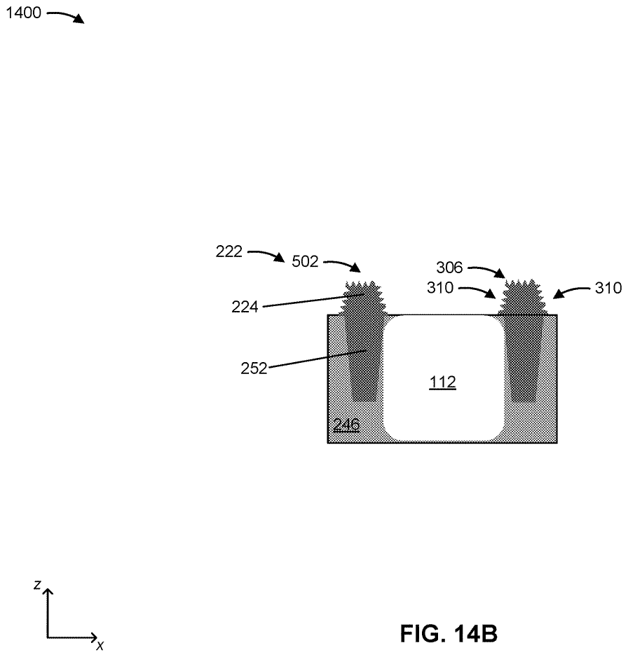

FIGS. 14A and 14B are diagrams of an example implementation 1400 of forming cavities 502 in a metal grid structure 224 of a pixel sensor array 222 described herein. The techniques described in connection with FIGS. 14A and 14B may be used to form cavities 502 in the examples of the pixel sensor arrays 222 illustrated and described in connection with FIGS. 5C, 5D, 5E, 5H, 5I, and 5J (e.g., the examples in which the cavities 502 are included in the top surfaces 306 and in the sidewalls 310 of the metal grid structures 224). In some implementations, one or more of the semiconductor processing operations described in connection with FIGS. 14A and 14B may be performed using one or more semiconductor processing tools, such as a deposition tool, an exposure tool, a developer tool, an etch tool, a planarization tool, a plating tool, an ion implantation tool, and/or a wafer/die transport tool, among other examples.

The example implementation 1400 is similar to the example implementation 1300 of forming cavities 502 in the metal grid structure 224. However, as shown in FIG. 14A, a pattern 1402 is formed in the masking layer 1302, and the pattern 1402 includes openings over the sidewalls 310 of the metal grid structure 224 as well as over the top surfaces 306 of the metal grid structure 224. An etch tool may be used to etch the top surfaces 306 of the metal grid structure 224 based on the pattern 1402 in the masking layer 1302 to form the cavities 502 in the top surfaces 306 of the metal grid structure 224 as well as to form cavities 502 in the sidewalls 310 of the metal grid structure 224, as shown in FIG. 14B.

As indicated above, FIGS. 14A and 14B are provided as an example. Other examples may differ from what is described with regard to FIGS. 14A and 14B.

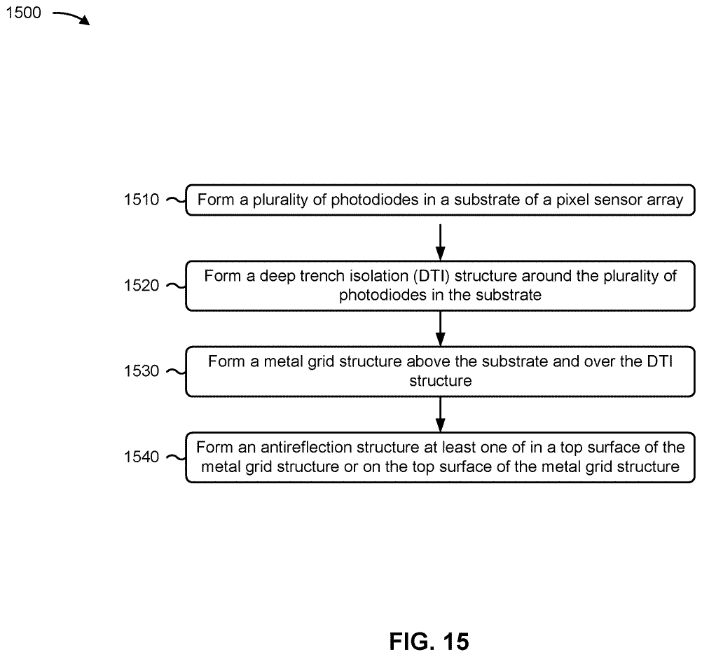

FIG. 15 is a flowchart of an example process 1500 associated with forming a metal grid structure of a pixel sensor array. In some implementations, one or more process blocks of FIG. 15 are performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 15, process 1500 may include forming a plurality of photodiodes in a substrate of a pixel sensor array (block 1510). For example, one or more semiconductor processing tools may be used to form a plurality of photodiodes 112 in a substrate 246 of a pixel sensor array 222, as described herein.

As further shown in FIG. 15, process 1500 may include forming a DTI structure around the plurality of photodiodes in the substrate (block 1520). For example, one or more semiconductor processing tools may be used to form a DTI structure 252 around the plurality of photodiodes 112 in the substrate 246, as described herein.

As further shown in FIG. 15, process 1500 may include forming a metal grid structure above the substrate and over the DTI structure (block 1530). For example, one or more semiconductor processing tools may be used to form a metal grid structure 224 above the substrate 246 and over the DTI structure 252, as described herein. In some implementations, the DTI structure 252 laterally surrounds the plurality of photodiodes 112.

As further shown in FIG. 15, process 1500 may include forming an antireflection structure at least one of in a top surface of the metal grid structure or on the top surface of the metal grid structure (block 1540). For example, one or more semiconductor processing tools may be used to form an antireflection structure at least one of in a top surface 306 of the metal grid structure 224 or on the top surface 306 of the metal grid structure 224, as described herein. In some implementations, the antireflection structure includes an antireflective layer 404 on the top surface 306 of the metal grid structure 224. In some implementations, the antireflection structure includes a plurality of nanostructures 304 on the top surface 306 of the metal grid structure 224. In some implementations, the antireflection structure includes a plurality of nanostructures 304 formed on an antireflective layer 902 on the top surface 306 of the metal grid structure 224. In some implementations, the antireflection structure includes a plurality of cavities 502 formed in the top surface 306 of the metal grid structure 224.

Process 1500 may include additional implementations, such as any single implementation or any combination of implementations described below and/or in connection with one or more other processes described elsewhere herein.

In a first implementation, forming the antireflection structure includes depositing a layer of dielectric material (e.g., the antireflective layer 402, the antireflective layer 902) on the metal grid structure 224 and on the semiconductor layer 246, and removing portions of the layer of dielectric material such that remaining portions of the layer of dielectric material correspond to the antireflection layer (e.g., the antireflective layer 402, the antireflective layer 902) on the top surface 306 of the metal grid structure 224.

In a second implementation, alone or in combination with the first implementation, removing the portions of the layer of dielectric material includes removing the portions of the layer of dielectric material from sidewalls 310 of the metal grid structure 224.

In a third implementation, alone or in combination with one or more of the first and second implementations, process 1500 includes performing a thermal anneal operation to form nanowires (e.g., nanostructures 304) on the antireflection layer.

In a fourth implementation, alone or in combination with one or more of the first through third implementations, forming the antireflection layer includes forming a pattern (e.g., a pattern 1304, a pattern 1402) in a masking layer 1302 on the metal grid structure 224, and etching the top surface 306 of the metal grid structure 224 based on the pattern to form a plurality of cavities 502 in the top surface 306 of the metal grid structure 224, wherein the plurality of cavities 502 correspond to the antireflection structure in the top surface 306 of the metal grid structure 224.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

In this way, an image sensor device may include one or more types of antireflection structures on a metal grid surrounding the pixel sensors in a pixel sensor array of the image sensor device. The antireflection structures may include an antireflective layer, nanostructures extending from the antireflective layer, and/or a plurality of cavities formed in the metal grid structure. The antireflection structures may be included in and/or on one or more surfaces of the metal grid structure to reduce the reflection of incident light, which may reduce the likelihood and/or magnitude of optical crosstalk between adjacent pixel sensors in the pixel sensor array.

As described in greater detail above, some implementations described herein provide a pixel sensor array. The pixel sensor array includes a plurality of pixel sensors, arranged in a grid, comprising a plurality of photodiodes in a substrate. The pixel sensor array includes a DTI structure, laterally surrounding the plurality of photodiodes, in the substrate. The pixel sensor array includes a metal grid structure above the DTI structure and above the substrate, where the metal grid structure surrounds the photodiodes. The pixel sensor array includes an antireflective layer on a top surface of the metal grid structure. The top surface faces away from the substrate.

As described in greater detail above, some implementations described herein provide an image sensor device. The image sensor device includes a plurality of pixel sensors, arranged in a pixel sensor array, that include a plurality of photodiodes in a substrate of the image sensor device. The image sensor device includes a DTI structure, around the plurality of photodiodes, in the substrate. The image sensor device includes a metal grid structure above the DTI structure and above the semiconductor layer, where the metal grid structure surrounds the photodiodes, and where the metal grid structure includes a plurality of concave surfaces in a top surface of the metal grid structure.

As described in greater detail above, some implementations described herein provide a method. The method includes forming a plurality of photodiodes in a substrate of a pixel sensor array. The method includes forming a DTI structure around the plurality of photodiodes in the substrate. The method includes forming a metal grid structure above the substrate and over the DTI structure. The method includes forming an antireflection structure at least one of in a top surface of the metal grid structure or on the top surface of the metal grid structure.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor array, comprising:
a substrate;
a plurality of photodiodes in the substrate;
a deep trench isolation (DTI) structure in the substrate, wherein at least a portion of the DTI structure is laterally between adjacent photodiodes of the plurality of photodiodes;
a metal grid structure over the substrate, wherein at least a portion of the metal grid structure is over a region of the substrate between the adjacent photodiodes; and
an antireflective layer on at least one surface of the metal grid structure, wherein the antireflective layer comprises zinc oxide, aluminum oxide, aluminum-doped zinc oxide, or a combination thereof.

2. The pixel sensor array of claim 1, wherein the at least one surface comprises:
a top surface of the metal grid structure that faces away from the substrate; and
one or more sidewalls of the metal grid structure.

3. The pixel sensor array of claim 1, wherein the antireflective layer has a thickness included in a range of approximately 50 nanometers to approximately 200 nanometers.

4. The pixel sensor array of claim 1, wherein the metal grid structure has a substantially trapezoidal cross-sectional profile in which a width of the metal grid structure increases in a direction from a top surface of the metal grid structure toward the substrate.

5. The pixel sensor array of claim 1, further comprising:
a plurality of nanostructures extending from the antireflective layer.

6. The pixel sensor array of claim 5, wherein the plurality of nanostructures comprises carbon nanowires having respective lengths included in a range of approximately 80 nanometers to approximately 1000 nanometers.

7. The pixel sensor array of claim 1, further comprising:
a plurality of color filter regions in respective openings of the metal grid structure and over respective photodiodes of the plurality of photodiodes; and
a plurality of micro-lenses over respective color filter regions of the plurality of color filter regions.

8. An image sensor device, comprising:
a substrate;
a plurality of photodiodes in the substrate;
a deep trench isolation (DTI) structure in the substrate, wherein at least a portion of the DTI structure is laterally between adjacent photodiodes of the plurality of photodiodes;
a metal grid structure over the substrate, wherein:
at least a portion of the metal grid structure is over a region of the substrate between the adjacent photodiodes; and
a top surface of the metal grid structure defines a first plurality of recesses; and
one or more sidewalls of the metal grid structure define a second plurality of recesses.

9. The image sensor device of claim 8, wherein the first plurality of recesses and the second plurality of recesses each have a rounded cross-sectional profile.

10. The image sensor device of claim 8, wherein the first plurality of recesses and the second plurality of recesses each have a substantially V-shaped cross-sectional profile.

11. The image sensor device of claim 8, wherein:
the first plurality of recesses has a substantially V-shaped cross-sectional profile; and
the second plurality of recesses has a rounded cross-sectional profile.

12. The image sensor device of claim 8, wherein:
respective depths of the first plurality of recesses are included in a range of approximately 1 nanometer to approximately 10 nanometers;
respective widths of the first plurality of recesses are included in a range of approximately 1 nanometer to approximately 50 nanometers; and
a spacing between adjacent recesses of the first plurality of recesses is included in a range of approximately 1 nanometer to approximately 5 nanometers.

13. The image sensor device of claim 8, wherein the metal grid structure has a substantially trapezoidal cross-sectional profile in which a width of the metal grid structure increases in a direction from the top surface toward the substrate.

14. The image sensor device of claim 8, wherein the metal grid structure has a substantially square-shaped cross-sectional profile in which the one or more sidewalls are substantially perpendicular to the top surface.

15. A method, comprising:
forming a plurality of photodiodes in a substrate;
forming a deep trench isolation (DTI) structure in the substrate such that at least a portion of the DTI structure is laterally between adjacent photodiodes of the plurality of photodiodes;
forming a metal grid structure over the substrate such that at least a portion of the metal grid structure is over a region of the substrate between the adjacent photodiodes; and
etching a top surface and one or more sidewalls of the metal grid structure to form:
a first plurality of recesses in the top surface; and
a second plurality of recesses in the one or more sidewalls.

16. The method of claim 15, wherein etching the top surface and the one or more sidewalls comprises:
forming a masking layer over the top surface and the one or more sidewalls of the metal grid structure;
forming a pattern in the masking layer, wherein the pattern includes:
a first plurality of openings over the top surface; and
a second plurality of openings over the one or more sidewalls; and
etching the metal grid structure through the first plurality of openings and the second plurality of openings.

17. The method of claim 16, wherein forming the pattern in the masking layer comprises:
exposing portions of the masking layer corresponding to the first plurality of openings and the second plurality of openings; and
developing the masking layer after exposing the portions of the masking layer.

18. The method of claim 15, wherein etching the top surface and the one or more sidewalls comprises performing a wet etch operation, and wherein the first plurality of recesses has a rounded cross-sectional profile.

19. The method of claim 15, wherein etching the top surface and the one or more sidewalls comprises performing a dry etch operation, and wherein the first plurality of recesses has a substantially V-shaped cross-sectional profile.

20. The method of claim 15, wherein forming the metal grid structure comprises:
performing a dry etch operation on a metal layer; and
selecting one or more parameters of the dry etch operation such that the metal grid structure has a substantially trapezoidal cross-sectional profile in which sidewalls of the metal grid structure are angled relative to the top surface.
